(19) United States
(12) Patent Application Publication
(10) Pub. No.: US 2026/0311772 A1
(43) Pub. Date: Oct. 8, 2026

(54) MEMORY DEVICE WITH A PRECHARGE CIRCUIT

(71) Applicant: Taiwan Semiconductor Manufacturing Company, Ltd., Hsinchu (TW)

(72) Inventors: Ayumu Yamada, Hsinchu (TW); Ryota Watanabe, Hsinchu (TW)

(21) Appl. No.: 19/172,417

(22) Filed: Apr. 7, 2025

(51) Int. Cl. G11C 16/26; G11C 16/04; G11C 16/24

(52) U.S. Cl. CPC G11C 16/26; G11C 16/0433; G11C 16/24

(57) ABSTRACT

A semiconductor device may include a memory array having a bit line and a memory cell coupled to the bit line. The semiconductor device further includes a sensing circuit to sense data from the memory cell. The semiconductor device further including a pre-charge circuit having an asymmetric clocked inverter having an input terminal, an output terminal, and at least one enable terminal. The input terminal is connected to the bit line. The output terminal is connected to the bit line. In response to receiving an enable signal on the at least one enable terminal, the pre-charge circuit pre-charges the bit line to a pre-charge voltage. The pre-charge voltage is higher than a threshold voltage of a sensing circuit and lower than the supply voltage.

### BACKGROUND

Memory devices, such as Read only memories (“ROMs”), Static Random Access Memory (SRAM), Resistive Random Access Memory (RRAM), Magnetic Random Access Memory (MRAM), include a plurality of cells disposed in rows and columns to form an array. Memory cells of a column are connected to a bit line, which is in turn connected to a sense amplifier. When performing a read operation on a target memory cell of the column of memory cells corresponding to a predetermined address, the bit line is charged to a predetermined voltage level (also known as a pre-charge phase of a read operation), and then the memory cell is coupled to the bit line in order to change a voltage level of the bit line in response to the datum stored in the memory cell (also known as an evaluation phase of a read operation). The sense amplifier then converts the voltage level on the bit line to either a logic 1 output or a logic 0 output (also known as an output phase of a read operation). Therefore, the time for performing a read operation is determined by many factors including, among other things, the time required to charge the bit line to the predetermined voltage level and the time required to discharge during an evaluation phase.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating a portion of a memory device in accordance with some embodiments.

FIG. 2 is a timing diagram illustrating signals of a memory device during a read operation in accordance with some embodiments.

FIG. 3 is a block diagram of a pre-charge circuit in accordance with some embodiments.

FIG. 4A is a first example circuit diagram of the pre-charge circuit of FIG. 3 in accordance with some embodiments.

FIG. 4B is a graph illustrating input and output signals of the pre-charge circuit of first example circuit diagram of FIG. 4A in accordance with some embodiments.

FIG. 4C is a timing diagram illustrating signals when the pre-charge circuit of first example circuit diagram of FIG. 4A is used for high pre-charging a bit line BL, in accordance with some embodiments.

FIG. 4D is a second example circuit diagram of the pre-charge circuit of FIG. 3 in accordance with some embodiments.

FIG. 4E is a third example circuit diagram of the pre-charge circuit of FIG. 3 in accordance with some embodiments.

FIG. 4F is a fourth example circuit diagram of the pre-charge circuit of FIG. 3 in accordance with some embodiments.

FIG. 5A is a graph illustrating the input and output signals of the pre-charge circuit when the pre-charge circuit of first example circuit diagram of FIG. 4A is used for low pre-charging a bit line BL in accordance with some embodiments.

FIG. 5B is a timing diagram illustrating signals when the pre-charge circuit of first example circuit diagram of FIG. 4A is used for high pre-charging a bit line BL in accordance with some embodiments.

FIG. 6 is a block diagram of an enhanced pre-charge circuit in accordance with some embodiments.

FIG. 7A is a first example circuit diagram of the enhanced pre-charge circuit of FIG. 6 in accordance with some embodiments.

FIG. 7B is a timing diagram illustrating signals when enhanced pre-charge circuit of first example circuit diagram of FIG. 7A is used for high pre-charging the bit line BL in accordance with some embodiments.

FIG. 7C is a second example circuit diagram of the enhanced pre-charge circuit of FIG. 6 in accordance with some embodiments.

FIG. 7D is a third example circuit diagram of the enhanced pre-charge circuit of FIG. 6 in accordance with some embodiments.

FIG. 7E is a fourth example circuit diagram of the enhanced pre-charge circuit of FIG. 6 in accordance with some embodiments.

FIG. 8 is a block diagram of an enhanced low pre-charge circuit in accordance with some embodiments.

FIG. 9A is a first example circuit diagram of the enhanced low pre-charge circuit of FIG. 8 in accordance with some embodiments.

FIG. 9B is a timing diagram illustrating signals when enhanced low pre-charge circuit of first example circuit diagram of FIG. 9A is used for low pre-charging the bit line BL in accordance with some embodiments.

FIG. 9C is a second example circuit diagram of the enhanced low pre-charge circuit of FIG. 8 in accordance with some embodiments.

FIG. 9D is a third example circuit diagram of the enhanced low pre-charge circuit of FIG. 8 in accordance with some embodiments.

FIG. 9E is a fourth example circuit diagram of the enhanced low pre-charge circuit of FIG. 8 in accordance with some embodiments.

FIG. 10 is a timing diagram illustrating signals of a memory device during a read operation with high pre-charged bit line BL in accordance with some embodiments.

FIG. 11 is a timing diagram illustrating signals of a memory device during a read operation with low pre-charged bit line BL in accordance with some embodiments.

FIG. 12 is a block diagram of a voltage-controlled pre-charge circuit in accordance with some embodiments.

FIG. 13 is an example circuit diagram of a pre-charge circuit of voltage-controlled pre-charge circuit of FIG. 12 in accordance with some embodiments.

FIG. 14A is a first example circuit diagram of a voltage detector circuit of voltage-controlled pre-charge circuit of FIG. 12 in accordance with some embodiments.

FIG. 14B is a graph 530 illustrating signals at the input and output terminals of voltage detector circuit 520 associated with first example circuit diagram of FIG. 14A in accordance with some embodiments.

FIG. 14C is a timing diagram of signals of the voltage-controlled pre-charge circuit of first example circuit diagram of FIG. 14A in accordance with some embodiments.

FIG. 14D is a second example circuit diagram of a voltage detector circuit of voltage-controlled pre-charge circuit of FIG. 12 in accordance with some embodiments.

FIG. 14E is a third example circuit diagram of a voltage detector circuit of voltage-controlled pre-charge circuit of FIG. 12 in accordance with some embodiments.

FIG. 14F is an example graph illustrating signals at the input and output terminals of the voltage detector circuit associated with each of the second example circuit diagram of FIG. 14D and the third example circuit diagram of FIG. 14E in accordance with some embodiments.

FIG. 15A is a block diagram of a voltage-controlled low pre-charge circuit in accordance with some embodiments.

FIG. 15B is an example circuit diagram of the low pre-charge circuit of FIG. 15A in accordance with some embodiments.

FIG. 15C is a graph illustrating signals at the input and output terminals of the low voltage detector circuit of FIG. 15A in accordance with some embodiments.

FIG. 15D is a timing diagram of signals of the voltage-controlled low pre-charge circuit of FIG. 15A in accordance with some embodiments.

FIG. 16A is a block diagram of an enhanced voltage-controlled pre-charge circuit in accordance with some embodiments.

FIG. 16B is a first example circuit diagram of the enhanced voltage detector circuit of FIG. 16A in accordance with some embodiments

FIG. 16C is a timing diagram of signals of the enhanced voltage-controlled pre-charge circuit of the first example circuit diagram of FIG. 16B in accordance with some embodiments.

FIG. 16D is a second example circuit diagram of the enhanced voltage detector circuit of FIG. 16A in accordance with some embodiments.

FIG. 16E is a third example circuit diagram of a voltage detector circuit of FIG. 16A in accordance with some embodiments.

FIG. 17A is a block diagram of an enhanced voltage-controlled low pre-charge circuit in accordance with some embodiments.

FIG. 17B is a timing diagram of signals of enhanced voltage-controlled low pre-charge circuit in accordance with some embodiments.

FIG. 18 is a flow diagram illustrating a method for performing a read or write operation in a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Further, when a first element is described as being “connected” or “coupled” to a second element, such description includes embodiments in which the first and second elements are directly connected or coupled to each other, and also includes embodiments in which the first and second elements are indirectly connected or coupled to each other with one or more other intervening elements in between

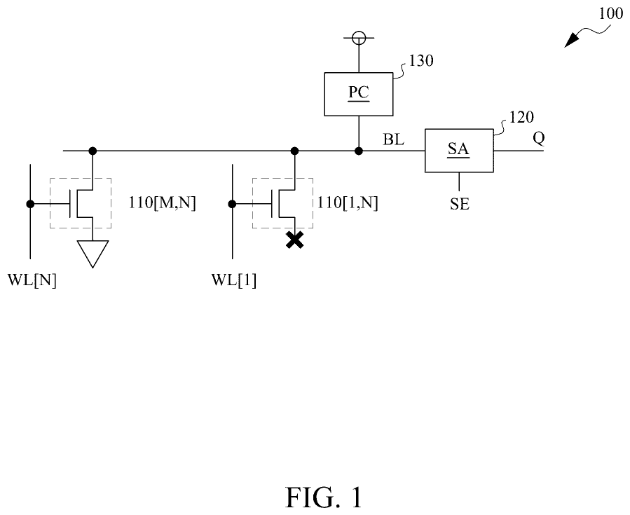

FIG. 1 illustrates a portion 100 of a memory device in accordance with various embodiments. In one example, portion 100 is a column of a memory device. The memory device includes a plurality of memory cells arranged in a matric of a plurality of rows and a plurality of columns. Each of the plurality of rows includes a first plurality of memory cells that are connected to a word line of a plurality of word lines. In addition, each of the plurality of columns includes a second plurality of memory cells. Each of the second plurality of memory cells of a column is connected to a bit line BL or a bit line bar BLB.

In one example, portion 100 is a Nth column of a memory device with M rows, and includes M number of memory cells, for example, memory cell 110[1,N], ..., memory cell 110[M, N]. Memory cell 110[1,N] is connected to word line WL[1], continuing to memory cell 110[M, N] that is connected to word line [N]. Memory cell 110[M, N] is an on cell, that is, a source grounded n-channel Metal Oxide Semiconductor (NMOS) transistor. Memory cell 110[1,N] is an off cell, that is, a source floating n-channel Metal Oxide Semiconductor (NMOS) transistor. In portion 100, memory cell 110[1,N], ..., memory cell 110[M, N] are shown to be NMOS based memory cells, however, it can be can be PMOS based memory cells, or a combination of NMOS based and PMOS based memory cell.

Memory cell 110[1,N], .., memory cell 110[M, N] are connected to a bit line BL. For a read or a write operation on any of memory cells 110[1,N], ..., 110[M, N], the bit line BL is pre-charged. A pre-charge circuit 130 pre-charges the bit line BL to a predetermined voltage. In addition, a word line WL associated with a selected memory cell is asserted. Asserting the word line activates the selected memory cell. The bit line BL is then connected to a sensing circuit 120. Sensing circuit 120 is enabled using a Sense Enable (SE) signal, and when enabled, sensing circuit 120 senses the change in the voltage on the bit line BL. Based on the bit line BL voltage, sensing circuit 120 provides the sensed data as an output Q.

Pre-charge circuit 130 is configured to improve a cycle time and an access time for the read operation. For example, and as discussed above, during a read operation, the bit line BL is pre-charged prior to memory cell activation (that is, prior to a word line WL being activated) and the bit line BL discharges through a selected memory cell. If the selected memory cell is an on-cell (that is, a source-grounded NMOS transistor), the bit line BL is discharged through the selected memory cell. Conversely, if the selected memory cell is an off-cell (that is, a source-floating NMOS transistor), the bit line BL voltage remains high. The state of the selected cell, whether on or off (that is, 0 or 1), is detected by sensing the bit line BL voltage. Hence, the cycle time and the access time for the read operation is dominated by the sensing time and the pre-charge time.

Pre-charge circuit 130 is designed and configured to reduce the pre-charge time and the sensing during a read operation on a memory device. For example, pre-charge circuit 130 pre-charges the bit line BL associated with the selected memory cell to a pre-determined voltage (also referred to as a pre-charge voltage VPC) that is less than the supply voltage VDD and greater than a threshold voltage of sensing circuit 120. Since, the bit line BL is not being charged all the way to the supply voltage VDD, it results in decreased pre-charge time during the read operation. For a PMOS based memory cell, pre-charge circuit 130 pre-charges the bit line BL associated with the selected memory cell to a pre-determined voltage that is less than the threshold voltage of sensing circuit 120 but greater than 0 volts.

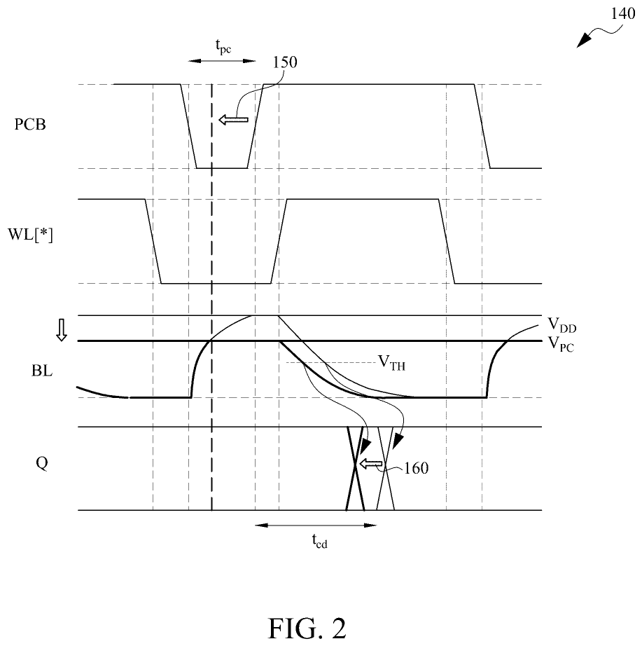

FIG. 2 is a timing diagram illustrating signals of a memory device during a read operation. As shown in FIG. 2, the pre-charge bar PCB signal drops to a logic low triggering pre-charging of the bit line BL. This ensues pre-charging of the bit line BL to a pre-charge voltage VPC that is lower than the supply voltage VDD. A time to pre-charge the bit line BL to the pre-charge voltage VPC is indicated as a pre-charge time t_{PC}. As indicated by arrow 150 in FIG. 2, the pre-charge time t_{PC} for charging the bit line BL to the pre-charge voltage VPC is less than the pre-charge time t_{PC} for charging the bit line BL to the supply voltage VDD.

Continuing with FIG. 2, after pre-charging of the bit line BL, the word line WL is asserted. Asserting the word line WL leads to activation of the selected memory cell and discharge of the bit line BL from the pre-charge voltage VPC (or the supply voltage VDD in a conventional read operation) through the selected memory cell. The SCE signal is triggered when the bit line BL voltage drops to a read voltage VR for sensing the data stored in the selected memory cell by sensing circuit 120. As shown in FIG. 2, the discharging of the bit line BL will be faster from the pre-charge voltage VPC compared to from the supply voltage VDD. This results in a smaller clock to data time Tcd, as indicated by arrow 160. Therefore, pre-charge circuit 130 enables a faster read operation in a memory device compared to a conventional pre-charge circuit.

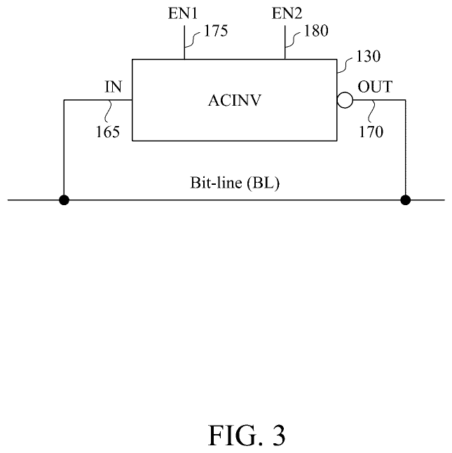

FIG. 3 is a block diagram of pre-charge circuit 130. In one example, pre-charge circuit 130 is an Asymmetric Clock Invertor (ACINV) circuit. An ACINV circuit has a different rising and falling edge delays and hence provides a configurable pre-charge voltage VPC. As shown in FIG. 3, pre-charge circuit 130 includes a first terminal 165 (also referred to as an input terminal) and a second terminal 170 (also referred to as an output terminal). Both first terminal 165 and second terminal 170 are connected to the bit line BL. Pre-charge circuit 130 further includes a first enable terminal 175 to receive a first enable EN1 signal and a second enable terminal 180 to receive a second enable EN2 signal. First enable EN1 signal and second enable EN2 signal activate pre-charge circuit 130 to pre-charge the bit line BL to a predetermined voltage. In some examples, and discussed in following sections of the disclosure, pre-charge circuit 130 can include more than or less than two enable terminals and hence can be enabled by more than or less than two enable signals.

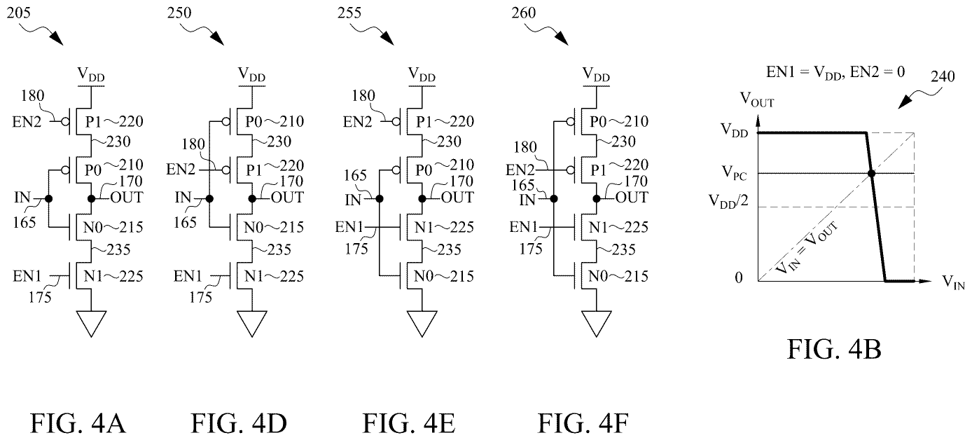

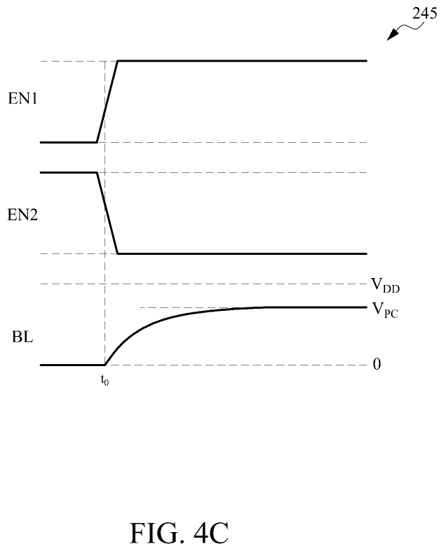

FIG. 4A is a first example circuit diagram 205 of pre-charge circuit 130. As illustrated in first example circuit diagram 205, pre-charge circuit 130 includes a first transistor 210, a second transistor 215, a third transistor 220, and a fourth transistor 225. In examples, each of first transistor 210 and third transistor 220 is a PMOS transistor, and each of second transistor 215 and fourth transistor 225 is a NMOS transistor. However, other types of transistors may be used for each of first transistor 210, second transistor 215, third transistor 220, and fourth transistor 225.

A first Source/Drain (S/D) structure of third transistor 220 is connected to the supply voltage VDD and a second S/D structure of third transistor 220 is connected to a first S/D structure of first transistor 210 at a first internal node 230. A second S/D structure of first transistor 210 is connected to a first S/D structure of second transistor 215 at an output node. The output node is connected to output terminal 170. A second S/D structure of second transistor 215 is connected to a first S/D structure of fourth transistor 225 at a second internal node 235. A second S/D structure of fourth transistor 225 is connected to the ground. A gate structure of first transistor 210 is connected to a gate structure of second transistor 215 at an input node that is connected to input terminal 165. Thus, first transistor 210 and second transistor 215 form a diode between first internal node 230 and second internal node 235. In addition, first transistor 210, second transistor 215, third transistor 220, and fourth transistor 225 are thus connected to form a ACINV circuit between input terminal 165 and output terminal 170. A gate structure of fourth transistor 225 is connected to first enable terminal 175 to receive the first enable EN1 signal and a gate structure of third transistor 220 is connected to second enable terminal 180 to receive the second enable EN2 signal.

Operation of first example circuit diagram 205 is explained in conjugation with FIGS. 4B and 4C. FIG. 4B is a graph 240 showing input and output signals of pre-charge circuit 130 as shown in first example circuit diagram 205 of FIG. 4A. As discussed above, first example circuit 205 is an ACINV circuit between input terminal 165 and output terminal 170. Therefore, and as shown in FIG. 4B, when the input signal is at a logic low, the output signal is a logic high, and when the input signal rises above the pre-charge voltage VPC, the output signal drops to a logic low. In addition, the coupling between input terminal 165 and output terminal 170 introduces an additional constraint of the input signal being approximately equal to the output signal. FIG. 4C is a timing diagram 245 illustrating signals of pre-charge circuit 130 when used for a high pre-charged bit line (that is, pre-charging the bit line BL to a pre-charge voltage VPC that is greater than a threshold voltage of sensing circuit 120).

As shown in FIG. 4C, for pre-charging the bit line BL, the first enable EN1 signal is asserted as a logic high (that is, to the supply voltage VDD) and the second enable EN2 signal is asserted as a logic low (that is, to the ground voltage or 0V). This causes third transistor 220 and fourth transistor 225 of pre-charge circuit 130 to be switched on. Also, since the bit line BL is not charged yet, the gate structures of both first transistor 210 and second transistor 215 are at a logic low thereby switching on first transistor 210 and switching off second transistor 215. This causes the output node, and hence, the bit line BL, to be connected to the supply voltage VDD and pre-charging of the bit line BL. When the voltage of the output node, and hence, the bit line BL rises to the threshold voltage of first transistor 210, first transistor 210 is switched off thereby disconnecting the output node, and hence, the bit line BL, from the supply voltage VDD.

For example, and as shown in FIG. 4C, the first enable EN1 signal is asserted as a logic high at a time t0. In addition, the second enable EN2 signal is asserted at a logic low at the time t0. The bit line BL signal starts to rise from the time t0 and stabilizes at the pre-charge voltage VPC. In some examples, the first enable EN1 signal and the second enable EN2 signal are not asserted simultaneously.

In addition, when the voltage on the input node is higher than a threshold voltage of second transistor 215, the output node is connected to the ground until the voltage on the input node falls below the threshold voltage of second transistor 215. Thus, the pre-charge voltage VPC for pre-charge circuit 130 can be set sufficiently larger than ½ VDD, for example, 0.6 VDD. In addition, the pre-charge voltage VPC can be configured or be tuned with a size of threshold voltage of first transistor 210 and second transistor 215. That is, the pre-charge voltage VPC can be increased by increasing a size of threshold voltage of first transistor 210 and vice versa.

FIG. 4D is a second example circuit diagram 250 of pre-charge circuit 130. As shown in FIG. 4D, the first S/D structure of first transistor 210 is connected to the supply voltage VDD and the second S/D structure of first transistor 210 is connected to the first S/D structure of third transistor 220 at first internal node 230. The second S/D structure of third transistor 220 is connected to the first S/D structure of second transistor 215 at the output node that is connected to output terminal 170. The second S/D structure of second transistor 215 is connected to the first S/D structure of fourth transistor 225 at second internal node 235. The second S/D structure of fourth transistor 225 is connected to the ground. The gate structure of first transistor 210 is connected to the gate structure of second transistor 215 at the input node that is connected to input terminal 165. The gate structure of third transistor 220 is connected to second enable terminal 180 to receive the second enable EN2 signal and the gate structure of fourth transistor 225 is connected to first enable terminal 175 to receive the first enable EN1 signal. Pre-charge circuit 130 of second example circuit diagram 250 functions similar to pre-charge circuit 130 of first example circuit diagram 205 with a different rate of pre-charge and hence is not being described again for brevity of disclosure.

FIG. 4E is a third example circuit diagram 255 of pre-charge circuit 130. As shown in FIG. 4E, the first S/D structure of third transistor 220 is connected to the supply voltage VDD and the second S/D structure of third transistor 220 is connected to the first S/D structure of first transistor 210 at first internal node 230. The second S/D structure of first transistor 210 is connected to the first S/D structure of fourth transistor 225 at the output node that is connected to output terminal 170. The second S/D structure of fourth transistor 225 is connected to the first S/D structure of second transistor 215 at second internal node 235. The second S/D structure of second transistor 215 is connected to the ground. The gate structure of first transistor 210 is connected to the gate structure of second transistor 215 at an input node that is connected to input terminal 165. The gate structure of third transistor 220 is connected to second enable terminal 180 to receive the second enable EN2 signal and the gate structure of fourth transistor 225 is connected to first enable terminal 175 to receive the first enable EN1 signal. Pre-charge circuit 130 of third example circuit diagram 255 functions similar to pre-charge circuit 130 of first example circuit diagram 205 with a different rate of pre-charge and hence is not being described again for brevity of disclosure.

FIG. 4F is a fourth example circuit diagram 260 of pre-charge circuit 130. As shown in FIG. 4F, the first S/D structure of first transistor 210 is connected to the supply voltage VDD and the second S/D structure of first transistor 210 is connected to the first S/D structure of third transistor 220 at first internal node 230. The second S/D structure of third transistor 220 is connected to the first S/D structure of fourth transistor 225 at the output node that is connected to the output terminal 170. The second S/D structure of fourth transistor 225 is connected to first S/D structure of second transistor 215 at second internal node 235. The second S/D structure of second transistor 215 is connected to the ground. The gate structure of first transistor 210 is connected to the gate structure of second transistor 215 at an input node that is connected to input terminal 165. The gate structure of third transistor 220 is connected to second enable terminal 170 to receive the second enable EN2 signal and the gate structure of fourth transistor 225 is connected to first enable terminal to receive the first enable EN1 signal. Pre-charge circuit 130 of fourth example circuit diagram 260 functions similar to pre-charge circuit 130 of first example circuit diagram 205 with a different rate of pre-charge and hence is not being described again for brevity of disclosure.

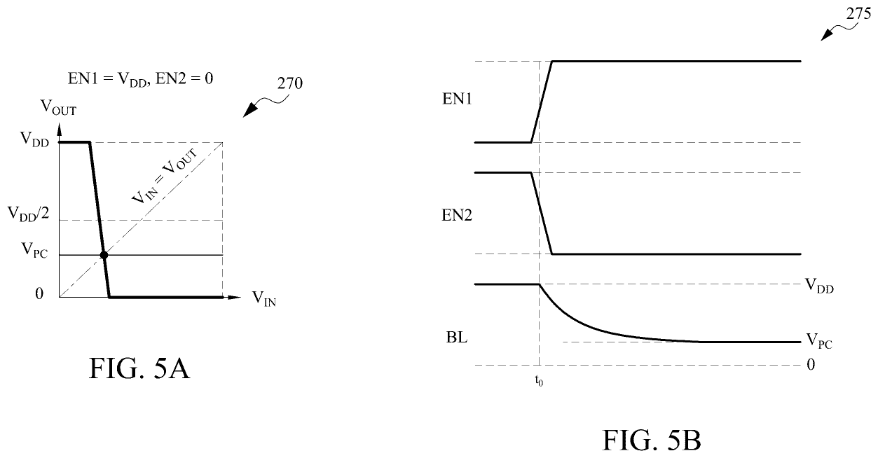

FIG. 5A is graph 270 illustrating signals of pre-charge circuit 130 when pre-charge circuit 130 of first example circuit diagram 204 of FIG. 4A is used for low pre-charging the bit line BL. Low pre-charging of the bit line BL is done when the selected memory cell of is a PMOS based memory cell. As shown in FIG. 5A, when the input signal is at a logic low, the output signal is a logic high, and when the input signal rises above the pew-charge voltage VPC, the output signal drops to a logic low. In addition, the coupling between input terminal 165 and output terminal 170 introduces an additional constraint of the input signal being approximately equal to the output signal. However, the pre-charge voltage VPC for the input signal to drop to a logic low is lower than the threshold voltage of sensing circuit 120 but higher than 0V.

FIG. 5B is a timing diagram 275 illustrating signals when the pre-charge circuit of first circuit diagram of FIG. 4A is used for low pre-charging a bit line BL. For low pre-charging the bit line BL, the first enable EN1 signal is asserted as a logic high and the second enable EN2 signal is asserted as a logic low. This causes third transistor 220 and fourth transistor 225 to be switched on. Also, since the bit line BL is at the supply voltage VDD (that is, a logic high), first transistor 210 is switched off and second transistor 215 is switched on. In addition, since the first enable EN1 signal is at a logic high, fourth transistor 225 is switched on. This causes the output node to be discharged through second transistor 215 and fourth transistor 225 to the ground. When the voltage of the output node reaches a threshold voltage of second transistor 215, second transistor 215 is switched off thereby discontinuing the discharge of the output node, and hence, the bit line BL, to the ground. Thus, the pre-charge voltage VPC for pre-charge circuit 130 can be set sufficiently smaller than the threshold voltage of sensing circuit 120, for example, 0.4 VDD. In addition, the threshold voltage for pre-charge circuit 130 can be tuned with a size of threshold voltage of first transistor 210 and second transistor 215.

As shown in FIG. 5B, the first enable EN1 signal is asserted as a logic high at a time t0. In addition, the second enable EN2 signal is asserted at a logic low at the time t0. The bit line BL voltage starts to drop from the supply voltage VDD at the time t0 and stabilizes at the pre-charge voltage VPC. In some examples, the first enable EN1 signal and the second enable EN2 signal are not asserted simultaneously when low pre-charging the bit line BL. That is, the pre-charge voltage VPC can be decreased by decreasing a size of threshold voltage of second transistor 215 and vice versa.

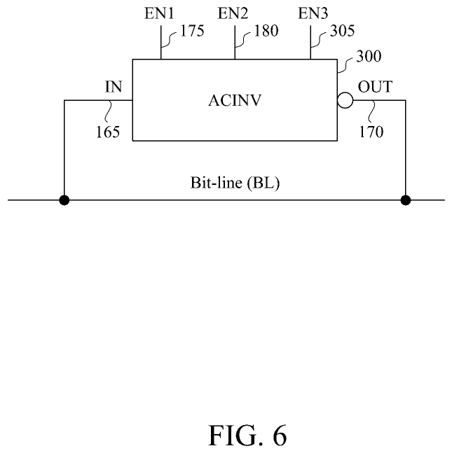

FIG. 6 is a block diagram of an enhanced pre-charge circuit 300. In one example, enhanced pre-charge circuit 300 is an ACINV circuit. As shown in FIG. 6, enhanced pre-charge circuit 300 includes an additional enable terminal, that is, a third enable terminal 305 compared to pre-charge circuit 130 of FIG. 3. Third enable terminal 305 is configured to receive a third enable EN3 signal. In addition, and as discussed in greater detail in the following sections of the disclosure, enhanced pre-charged circuit 300 includes an additional transistor. In examples, enhanced pre-charge circuit 300 enables faster high pre-charging of a line BL compared to pre-charge circuit 130 and provides better control over the pre-charge voltage VPC.

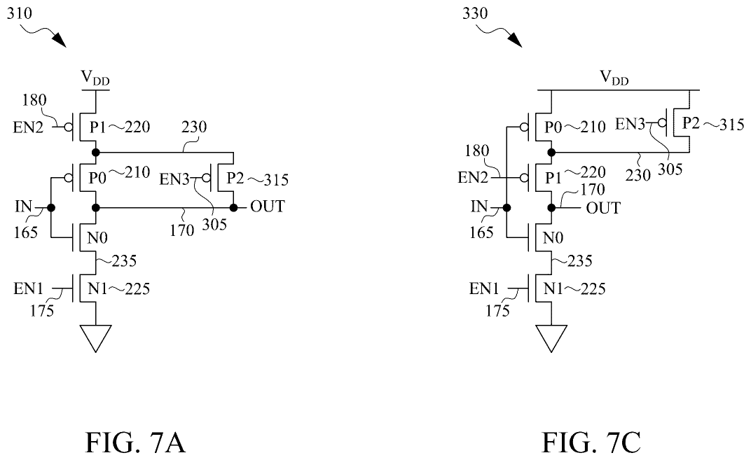

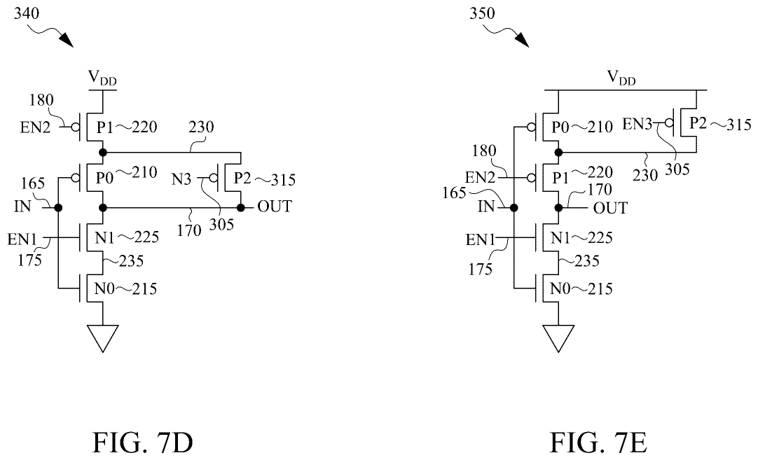

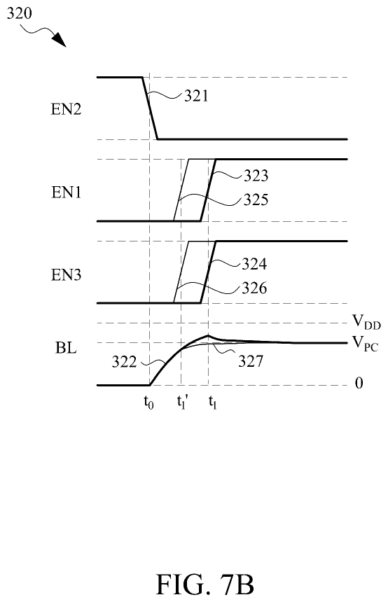

FIG. 7A is a first example circuit diagram 310 of enhanced pre-charge circuit 300. In examples, first example circuit diagram 310 is similar to first circuit diagram 205 of FIG. 4A, but with an additional transistor. As shown in FIG. 7A, enhanced pre-charge circuit 300 includes first transistor 210, second transistor 215, third transistor 220, fourth transistor 225, and an addition fifth transistor 315. Additional fifth transistor 315 is connected in parallel to first transistor 210. For example, and as shown in FIG. 7A, the first S/D structure of third transistor 220 is connected to the supply voltage VDD and the second S/D structure of third transistor 210 is connected to the first S/D structure of first transistor 210 at first internal node 230. The second S/D structure of first transistor 210 is connected to the first S/D structure of second transistor 215 at the output node that is connected to output terminal 170. The second S/D structure of second transistor 215 is connected to the first S/D structure of fourth transistor 225 at second internal node 235. The second S/D structure of fourth transistor 225 is connected to the ground. The gate structure of first transistor 210 is connected to the gate structure of second transistor 215 at the input node that is connected to input terminal 165. Thus, first transistor 210 and second transistor 215 form a diode between first internal node 230 and second internal node 235. The gate structure of fourth transistor 225 is connected first enable terminal 175 to receive the first enable EN1 signal and a gate structure of third transistor 220 is connected to second enable terminal 180 to receive the second enable EN2 signal.

Thus, first transistor 210, second transistor 215, third transistor 220, fourth transistor 225 of enhanced pre-charge circuit 300 are same as and are connected in a similar manner to that of first circuit diagram 205 of FIG. 4A of pre-charge circuit 130. In addition, a first S/D structure of fifth transistor 315 is connected to first internal node 230 and a second S/D structure of fifth transistor 315 is connected to the output node that is connected to output terminal 170. A gate structure of fifth transistor 315 is connected to third enable terminal 305 to receive the third enable signal EN3. Thus, fifth transistor 315 is connected in parallel to first transistor 210. In example embodiments, fifth transistor 315 is a PMOS transistor. However, fifth transistor 315 can be an NMOS transistor.

Enhanced pre-charge circuit 300 functions similar to pre-charge circuit 130 described above with respect to first example circuit diagram 204 of FIG. 4A. However, enhanced pre-charge circuit 300 pre-charges the bit line BL at a slightly lower time (that is, faster) and provides better control than pre-charge circuit 130. FIG. 7B is a timing diagram 320 illustrating signals of when enhanced pre-charge circuit 300 of first example circuit diagram 410 of FIG. 7A is used for high pre-charging the bit line BL. As shown in FIG. 7B, the second enable EN2 signal is asserted at a logic low at the time t0, indicated as 321. This switches on third transistor 220 in addition to first transistor 210, thereby connecting the bit line BL to the supply voltage. Therefore, the bit line BL signal starts to rise from the time t0 when the second enable EN2 signal is asserted, indicated as 322. Then, the first enable EN1 signal and the third enable EN3 signal are asserted as a logic high at a time t1, indicated as 323 and 324.

When the third enable EN3 signal is asserted as a logic high, it switches off fifth transistor 315. In addition, when the first enable EN1 signal is asserted as a logic high, it switches on second transistor 215. Therefore, when the first enable EN1 signal and the third enable EN3 signal are asserted at the time t1, the bit line BL signal rises above the pre-charge voltage VPC and then stabilizes at the pre-charge voltage VPC, indicated as 322. In an alternate example, the first enable EN1 signal and the third enable EN3 signal are asserted as a logic high at a time t1′ that is slightly before the time t1, indicated as 325 and 326. When the first enable EN1 signal and the third enable EN3 signal are asserted at the time t1′, the bit line BL signal rises to the pre-charge voltage VPC without rising above the pre-charge voltage VPC, indicated as 327. In some examples, the first enable EN1 signal and the second enable EN2 signal are not asserted simultaneously.

FIG. 7C is a second example circuit diagram 330 of enhanced pre-charge circuit 300. In examples, second example circuit diagram 330 is similar to second circuit diagram 250 of FIG. 4D, but with an additional transistor. For example, and as shown in FIG. 7C, first transistor 210, second transistor 215, third transistor 220, fourth transistor 225 of enhanced pre-charge circuit 300 of second example circuit diagram 320 are same as and are connected in a similar manner as second example circuit diagram 250 of FIG. 4D of pre-charge circuit 130. That is, and as shown in FIG. 7B, the first S/D structure of first transistor 210 is connected to the supply voltage VDD and the second S/D structure of first transistor 210 is connected to the first S/D structure of third transistor 220 at first internal node 230. The second S/D structure of third transistor 220 is connected to the first S/D structure of second transistor 215 at the output node connected to output terminal 170. The second S/D structure of second transistor 215 is connected to the first S/D structure of fourth transistor 225 at second internal node 235. The second S/D structure of fourth transistor 225 is connected to the ground. The gate structure of first transistor 210 is connected to the gate structure of second transistor 215 at the input node that is connected to input terminal 165. The gate structure of third transistor 220 is connected to second enable terminal 180 to receive the second enable EN2 signal and the gate structure of fourth transistor 225 is connected to first enable terminal 175 to receive the first enable EN1 signal.

In addition, fifth transistor 315 is connected in parallel to first transistor 210. That is, the first S/D structure of fifth transistor 315 is connected to the supply voltage and the second S/D structure of fifth transistor 315 is connected to first internal node 230. The gate structure of fifth transistor 315 is connected to third enable terminal 305 to receive the third enable signal EN3. Enhanced pre-charge circuit 300 of second example circuit diagram 330 functions similar to enhanced pre-charge circuit 300 of first example circuit diagram 310 with a different rate of pre-charge and hence is not being described again for brevity of disclosure.

FIG. 7D is a third example circuit diagram 340 of enhanced pre-charge circuit 300. First transistor 210, second transistor 215, third transistor 220, fourth transistor 225 of enhanced pre-charge circuit 300 in third example circuit diagram 340 are same as and are connected in a similar manner as third example circuit diagram 255 of pre-charge circuit 130 of FIG. 4E. That is, and as shown in FIG. 7C, the first S/D structure of third transistor 220 is connected to the supply voltage VDD and the second S/D structure of third transistor 220 is connected to the first S/D structure of first transistor 210 at first internal node 230. The second S/D structure of first transistor 210 is connected to the first S/D structure of fourth transistor 225 at the output node that is connected to output terminal 170. The second S/D structure of fourth transistor 225 is connected to the first S/D structure of second transistor 215 at second internal node 235. The second S/D structure of second transistor 215 is connected to the ground. The gate structure of first transistor 210 is connected to the gate structure of second transistor 215 at the input node that is connected to input terminal 165. The gate structure of third transistor 220 is connected to second enable terminal 180 to receive the second enable signal EN2 and the gate structure of fourth transistor 225 is connected to first enable terminal 175 to receive the first enable signal EN1.

In addition, fifth transistor 315 is connected in parallel to first transistor 210. That is, the first S/D structure of fifth transistor 315 is connected to first internal node 230 and the second S/D structure of fifth transistor 315 is connected to the output node that is connected to output terminal 170. The gate structure of fifth transistor 315 is connected to third enable terminal 305 to receive the third enable EN3 signal. Enhanced pre-charge circuit 300 of third example circuit diagram 340 functions similar to enhanced pre-charge circuit 300 of first example circuit diagram 310 with a different rate of pre-charge and hence is not being described again for brevity of disclosure.

FIG. 7E is a fourth example circuit diagram 350 of enhanced pre-charge circuit 300. First transistor 210, second transistor 215, third transistor 220, fourth transistor 225 of enhanced pre-charge circuit 300 of fourth example circuit diagram 340 are same as and are connected in a similar manner as fourth circuit diagram 260 of FIG. 4F of pre-charge circuit 130. That is, and as shown in FIG. 7D, the first S/D structure of first transistor 210 is connected to the supply voltage VDD and the second S/D structure of first transistor 210 is connected to the first S/D structure of third transistor 220 at first internal node 230. The second S/D structure of third transistor 220 is connected to the first S/D structure of fourth transistor 225 at the output node. The second S/D structure of fourth transistor 225 is connected to first S/D structure of second transistor 215 at second internal node 235. The second S/D structure of second transistor 215 is connected to the ground. The gate structure of first transistor 210 is connected to the gate structure of second transistor 215 at the input node that is connected to input terminal 165. The gate structure of third transistor 220 is connected to second enable terminal 170 to receive the second enable signal EN2 and the gate structure of fourth transistor 225 is connected to first enable terminal to receive the first enable signal EN1.

In addition, fifth transistor 315 is connected in parallel to first transistor 210. That is, the first S/D structure of fifth transistor 315 is connected to the supply voltage and the second S/D structure of fifth transistor 315 is connected to first internal node 230. The gate structure of fifth transistor 315 is connected to third enable terminal 305 to receive the third enable signal EN3. Enhanced pre-charge circuit 300 of fourth example circuit diagram 350 functions similar to enhanced pre-charge circuit 300 of first example circuit diagram 310 with a different rate of pre-charge and hence is not being described again for brevity of disclosure.

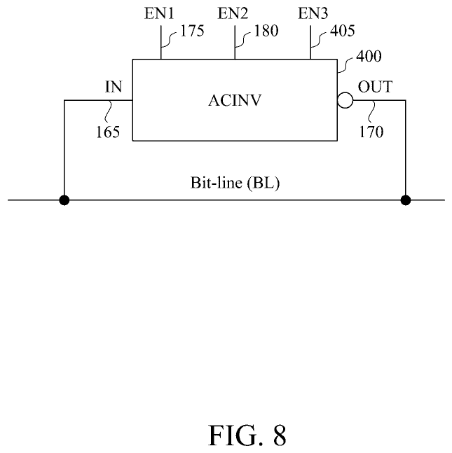

FIG. 8 is a block diagram of an enhanced low pre-charge circuit 400 for low pre-charging the bit line BL. In one example, enhanced low pre-charge circuit 400 is an ACINV circuit. As shown in FIG. 8, enhanced low pre-charge circuit 400 includes an additional enable terminal, that is, third enable terminal 405 compared to pre-charge circuit 130 of FIG. 3. Third enable terminal 405 is configured to receive a third enable EN3 signal. In addition, and as discussed in greater detail in the following sections of the disclosure, enhanced low pre-charge circuit 400 includes an additional transistor compared to pre-charge circuit 130 of FIG. 3.

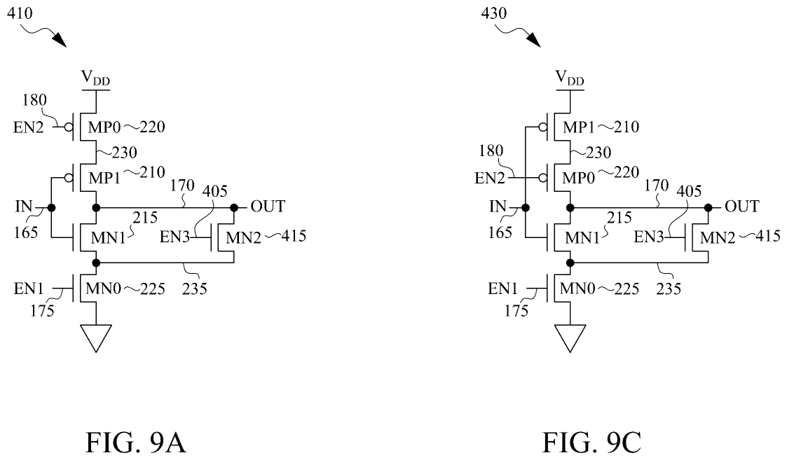

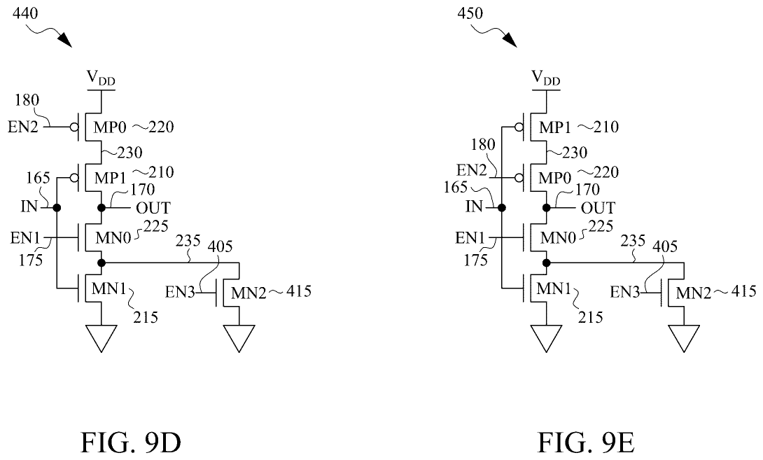

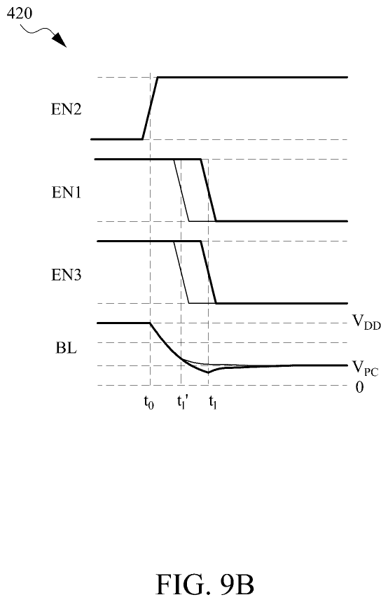

FIG. 9A is a first example circuit diagram 410 of enhanced low pre-charge circuit 400. As shown in FIG. 9A, low pre-charge circuit 400 includes first transistor 210, second transistor 215, third transistor 220, fourth transistor 225, and a fifth transistor 415. The first S/D structure of third transistor 220 is connected to the supply voltage VDD and the second S/D structure of third transistor 210 is connected to the first S/D structure of first transistor 210 at first internal node 230. The second S/D structure of first transistor 210 is connected to the first S/D structure of second transistor 215 at the output node that is connected to output terminal 170. The second S/D structure of second transistor 215 is connected to the first S/D structure of fourth transistor 225 at second internal node 235. The second S/D structure of fourth transistor 225 is connected to the ground. The gate structure of first transistor 210 is connected to the gate structure of second transistor 215 and to input terminal 165. Thus, first transistor 210 and second transistor 215 form a diode between first internal node 230 and second internal node 235. The gate structure of fourth transistor 225 is connected first enable terminal 175 to receive the first enable signal EN1 and a gate structure of third transistor 220 is connected to second enable terminal 180 to receive the second enable signal EN2.

Thus, first transistor 210, second transistor 215, third transistor 220, fourth transistor 225 of enhanced pre-charge circuit 300 are same as and are connected in a similar manner as first example circuit diagram 205 of pre-charge circuit 130 of FIG. 4A. In addition, a first S/D structure of fifth transistor 415 is connected to the output node that is connected to output terminal 170. A second S/D structure of fifth transistor 415 is connected to second internal node 235. A gate structure of fifth transistor 415 is connected to third enable terminal 405 to receive the third enable EN3 signal. Thus, fifth transistor 415 is connected in parallel to second transistor 215. In example embodiments, fifth transistor 415 is a NMOS transistor. However, fifth transistor 415 can be an PMOS transistor.

Enhanced low pre-charge circuit 400 functions like pre-charge circuit 130 described above with respect to first example circuit diagram 204 of FIG. 4A. However, enhanced low pre-charge circuit 400 pre-charges the bit line BL to a pre-charge voltage VPC that is lower than the threshold voltage of sensing circuit 120 and higher than 0V. In addition, enhanced low pre-charge circuit 400 pre-charges the bit line BL at a slightly lower time (that is, faster) than pre-charge circuit 130. FIG. 9B is a timing diagram 420 illustrating signals of when enhanced low pre-charge circuit 400 of first example circuit diagram 410 of FIG. 9A is used for low pre-charging the bit line BL.

As shown in FIG. 9B, the first enable EN1 signal is asserted as a logic high at the time t0. Asserting the first enable EN1 signal to a logic high switches on second transistor 215 thereby connected the bit line BL to the ground. Therefore, the bit line BL voltage begins to drop from a logic high from the time t0 when the first enable EN1 signal is asserted. The second enable EN2 signal and the third enable EN3 signal are asserted as a logic low at a time t1.

When the second enable EN2 signal is asserted as a logic low, third transistor 220 is switched on. And when the third enable EN3 signal is asserted as a logic low, fifth transistor 415 is switched off. Assertion of the second enable EN2 signal and the third enable EN3 arrests further discharging of the bit line BL. When the second enable EN2 signal and the third enable EN3 signal are asserted at the time t1, the bit line BL voltage drops below the pre-charge voltage VPC and then rises up to the pre-charge voltage VPC. In an alternate embodiment, the second enable EN2 signal and the third enable EN3 signal are asserted as a logic high at a time t1′ that is slightly before the time t1. When the second enable EN2 signal and the third enable EN3 signal are asserted at the time t1′, the bit line BL voltage drops to the pre-charge voltage VPC without dropping below the pre-charge voltage VPC. In some examples, the second enable EN2 signal and the third enable signal EN3 are not asserted simultaneously.

FIG. 9C is a second example circuit diagram 430 of enhanced pre-charge circuit 400. First transistor 210, second transistor 215, third transistor 220, fourth transistor 225 of enhanced pre-charge circuit 400 are same as and are connected in a similar manner as second circuit diagram 240 of pre-charge circuit 130 of FIG. 4B. That is, and as shown in FIG. 9B, the first S/D structure of first transistor 210 is connected to the supply voltage VDD and the second S/D structure of first transistor 210 is connected to the first S/D structure of third transistor 220 at first internal node 230. The second S/D structure of third transistor 220 is connected to the first S/D structure of second transistor 215 at the output node connected to output terminal 170. The second S/D structure of second transistor 215 is connected to the first S/D structure of fourth transistor 225 at second internal node 235. The second S/D structure of fourth transistor 225 is connected to the ground. The gate structure of first transistor 210 is connected to the gate structure of second transistor 215 and to input terminal 165. The gate structure of third transistor 220 is connected to second enable terminal 180 to receive the second enable EN2 signal and the gate structure of fourth transistor 225 is connected to first enable terminal 175 to receive the first enable EN1 signal.

In addition, fifth transistor 415 is connected in parallel to second transistor 215. That is, the first S/D structure of fifth transistor 415 is connected to the output node and the second S/D structure of fifth transistor 415 is connected to second internal node 235. The gate structure of fifth transistor 415 is connected to third enable terminal 405 to receive the third enable EN3 signal. Enhanced low pre-charge circuit 400 of second example circuit diagram 430 functions similar to enhanced low pre-charge circuit 400 of first example circuit diagram 410 with a different rate of pre-charge and hence is not being described again for brevity of disclosure.

FIG. 9D is a third example circuit diagram 440 of enhanced low pre-charge circuit 400. First transistor 210, second transistor 215, third transistor 220, fourth transistor 225 of enhanced pre-charge circuit 300 are same as and are connected in a similar manner as third circuit diagram 245 of pre-charge circuit 130 of FIG. 4C. That is, and as shown in FIG. 9D, the first S/D structure of third transistor 220 is connected to the supply voltage VDD and the second S/D structure of third transistor 220 is connected to the first S/D structure of first transistor 210 at first internal node 230. The second S/D structure of first transistor 210 is connected to the first S/D structure of fourth transistor 225 at the output node that is connected to output terminal 170. The second S/D structure of fourth transistor 225 is connected to the first S/D structure of second transistor 215 at second internal node 235. The second S/D structure of second transistor 215 is connected to the ground. The gate structure of first transistor 210 is connected to the gate structure of second transistor 215 and to input terminal 165. The gate structure of third transistor 220 is connected to second enable terminal 180 to receive the second enable signal EN2 and the gate structure of fourth transistor 225 is connected to first enable terminal 175 to receive the first enable EN1 signal.

In addition, fifth transistor 415 is connected in parallel to second transistor 215. That is, the first S/D structure of fifth transistor 415 is connected to second internal node 235 and the second S/D structure of fifth transistor 315 is connected to the ground. The gate structure of fifth transistor 415 is connected to third enable terminal 405 to receive the third enable EN3 signal. Enhanced low pre-charge circuit 400 of third example circuit diagram 440 functions similar to enhanced low pre-charge circuit 400 of first example circuit diagram 410 with a different rate of pre-charge and hence is not being described again for brevity of disclosure.

FIG. 9E is a fourth example circuit diagram 440 of enhanced low pre-charge circuit 400. First transistor 210, second transistor 215, third transistor 220, fourth transistor 225 of enhanced low pre-charge circuit 400 are same as and are connected in a similar manner as fourth circuit diagram 250 of pre-charge circuit 130 of FIG. 4D. That is, and as shown in FIG. 9E, the first S/D structure of first transistor 210 is connected to the supply voltage VDD and the second S/D structure of first transistor 210 is connected to the first S/D structure of third transistor 220 at first internal node 230. The second S/D structure of third transistor 220 is connected to the first S/D structure of fourth transistor 225 at the output node. The second S/D structure of fourth transistor 225 is connected to first S/D structure of second transistor 215 at second internal node 235. The second S/D structure of second transistor 215 is connected to the ground. The gate structure of first transistor 210 is connected to the gate structure of second transistor 215 and to input terminal 165. The gate structure of third transistor 220 is connected to second enable terminal 170 to receive the second enable signal EN2 and the gate structure of fourth transistor 225 is connected to first enable terminal to receive the first enable signal EN1.

In addition, fifth transistor 415 is connected in parallel to second transistor 215. That is, the first S/D structure of fifth transistor 415 is connected to second internal node 235 and the second S/D structure of fifth transistor 415 is connected to the ground. The gate structure of fifth transistor 415 is connected to third enable terminal 405 to receive the third enable signal EN3. Enhanced low pre-charge circuit 400 of fourth example circuit diagram 450 functions similar to enhanced low pre-charge circuit 400 of first example circuit diagram 410 with a different rate of pre-charge and hence is not being described again for brevity of disclosure.

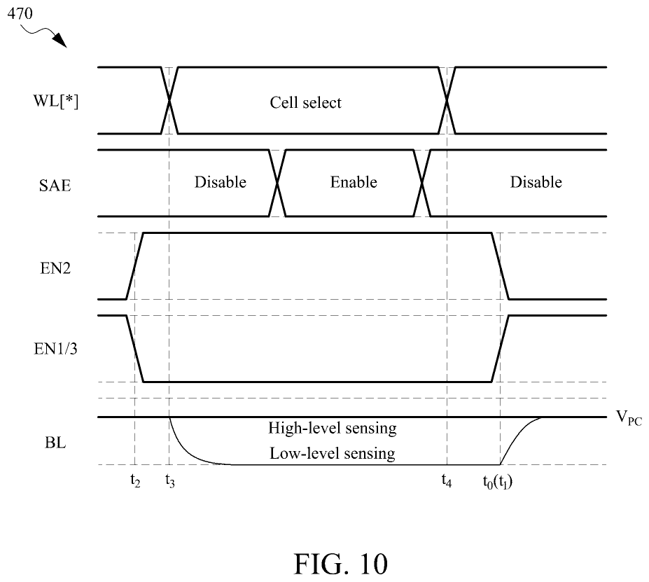

FIG. 10 is a timing diagram 470 illustrating signals of a memory device during a read operation with a high pre-charged bit line BL in accordance with some embodiments. As shown in FIG. 10, after the bit line BL is pre-charged to the pre-charge voltage VPC, the first enable EN1 signal is de-asserted as a logic low, the second enable EN2 signal is de-asserted as a logic high, and the third enable EN3 signal is de-asserted as a logic low at a time t2. Then, and as shown in FIG. 10, the word line WL signal is asserted at a logic high at a time t3. This leads to activation of the selected memory cell and hence discharge of the bit line BL signal. Then, and as shown in FIG. 10, the SE signal is asserted for enabling sensing circuit 120 for reading data from the selected memory cell. Once, sensing circuit 120 senses data from the selected memory cell, the word line WL signal is de-asserted at a time t4 thereby completing a read cycle. A next read cycle initiates again at time t0 where the first enable EN1 signal is asserted as a logic high, the second enable EN2 signal is asserted as a logic low, and the third enable EN3 signal is asserted as a logic high at the time t0 and t1 pre-charging the bit line to the pre-charge voltage VPC.

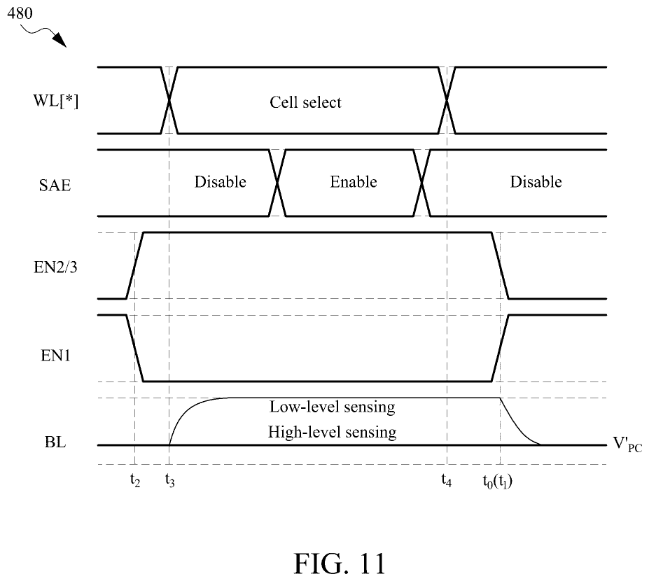

FIG. 11 is a timing diagram 480 illustrating signals of a memory device during a read operation with a low pre-charged bit line BL in accordance with some embodiments. As shown in FIG. 11, after the bit line BL is pre-charged to the pre-charge voltage VPC that is lower that a threshold voltage of sensing circuit 120 but higher than 0V, the first enable EN1 signal is de-asserted as a logic low, the second enable EN2 signal is de-asserted as a logic high, and the third enable EN3 signal is de-asserted as a logic high at a time t2. Then, and as shown in FIG. 11, the word line WL signal is asserted at a logic high at a time t3. This leads to activation of the selected memory cell and hence re-charge of the bit line BL signal. Then, and as shown in FIG. 11, the SE signal is asserted for enabling sensing circuit 120 for reading data from the selected memory cell. Once, sensing circuit 120 senses data from the selected memory cell, the word line WL signal is de-asserted at a time t4 thereby completing a read cycle. A next read cycle initiates again at time t0 where the first enable EN1 signal is re-asserted as a logic high, the second enable EN2 signal is re-asserted as a logic low, and the third enable EN3 signal is re-asserted as a logic low at the time t0 and t1 pre-charging the bit line to the pre-charge voltage VPC.

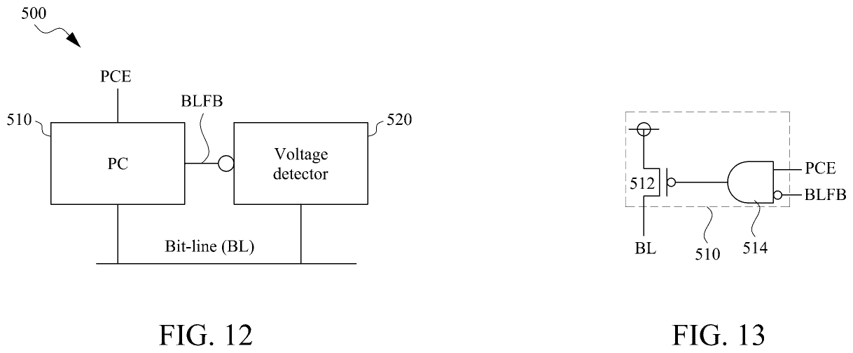

FIG. 12 is a block diagram of a voltage-controlled pre-charge circuit 500. Voltage-controlled pre-charge circuit 500 pre-charges a bit line BL to pre-charge voltage VPC for a read or a write operation that is greater than a threshold voltage of sensing circuit 120 but lower that the supply voltage VDD. As shown in FIG. 12, voltage-controlled pre-charge circuit 500 includes a pre-charge circuit 510 and a voltage detector circuit 520. Pre-charge circuit 510 includes a first terminal configured to receive a pre-charge enable PCE signal, a second terminal to receive a bit line feedback BLFB signal, and a third terminal connected to a bit line BL. In examples, pre-charge circuit 510 is enabled by the pre-charge enable PCE signal and pre-charges the bit line BL.

Voltage detector circuit 520 includes a first terminal connected to the bit line BL and a second terminal connected to the second terminal of pre-charge circuit 510. Voltage detector circuit 520 is configured to sense the bit line voltage, and generate and provide the bit line feedback BLFB signal to pre-charge circuit 510. Pre-charge circuit 510 then can alter pre-charging of the bit line BL based on the bit line feedback BLFB signal.

FIG. 13 is an example circuit diagram of pre-charge circuit 510. As shown on FIG. 13, pre-charge circuit 510 includes a first transistor 512 and a AND logic 514. A first S/D structure of first transistor 512 is connected to the supply voltage VDD and a second S/D structure of first transistor 512 is connected to the bit line. A gate structure of first transistor 512 is connected to an output terminal of AND logic 514. A first input terminal of AND logic 514 is connected to receive the pre-charge enable PCE signal and a second input terminal of AND logic 514 is connected to receive an inverse of the bit line feedback BLFB signal. In some examples, first transistor 512 is a NMOS transistor.

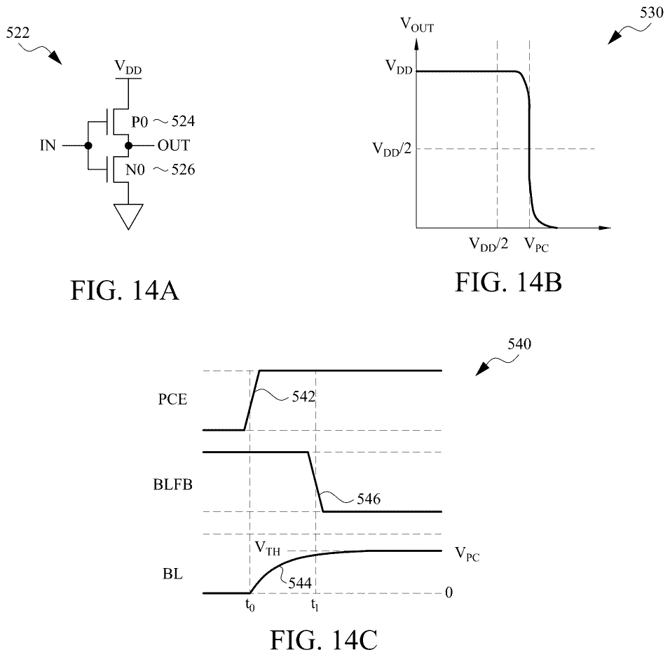

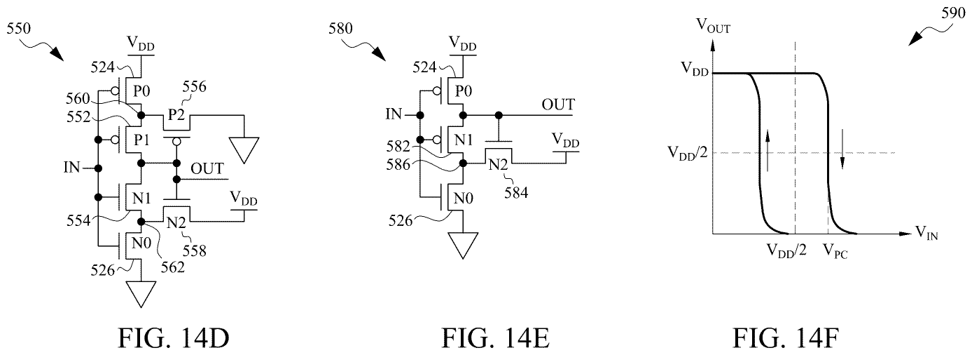

FIG. 14A is a first example circuit diagram 522 of voltage detector circuit 520. As shown in FIG. 14A, voltage detector circuit 520 includes a first transistor 524 and a second transistor 526. A first S/D structure of first transistor 524 is connected to the supply voltage VDD and a second S/D structure of first transistor 524 is connected to an output node that is connected to an output terminal. The output terminal is same as the second terminal of voltage detector circuit 520. Hence, the output terminal is connected to pre-charge circuit 510 and provides the bit line feedback BLFB signal to pre-charge circuit 510. A first S/D structure of second transistor 526 is connected to the output node and a second S/D structure of second transistor 526 is connected to the ground. A gate structure of first transistor 524 is connected to a gate structure of second transistor 526 at an input node that is connected to an input terminal. The input terminal is same as the first terminal of voltage detector circuit 520. Hence, the input terminal is connected to the bit line BL.

In first example circuit diagram 522 of voltage detector circuit 520, first transistor 524 is a PMOS transistor and second transistor 526 is a NMOS transistor. Thus, first transistor 524 and second transistor 526 form an invertor between the input terminal and the output terminal. In some examples, different types of transistors may be used for both first transistor 524 and second transistor 526.

FIG. 14B is a graph illustrating signals at the input and output terminals of voltage detector circuit 520 associated with first example circuit diagram of FIG. 14A. As shown in FIG, 14B, when the input signal Vin is lower than the pre-charge voltage VPC (that is, the bit line BL voltage is below the pre-charge voltage VPC), the output signal Vout (that is, the bit line feedback BLFB signal) is at a logic high. When the input signal (that is, the bit line BL voltage) reaches the pre-charge voltage VPC, the output signal Vout (that is, the bit line feedback BLFB signal) drops to a logic low.

FIG. 14C is a timing diagram 540 of signals of voltage-controlled pre-charge circuit 500 of first example circuit diagram 522 of FIG. 14A. As shown in FIG. 14C, the pre-charging of the bit-line BL is triggered when the pre-charge enable PCE signal rises to a logic high at time t0, indicated as 542. Since, the voltage of the bit line BL is below the pre-charge voltage VPC when the pre-charging of the bit-line BL is triggered, the output of voltage detector circuit 520 is a logic high. Hence, an output of AND logic 514 of pre-charge circuit is a logic high. This results in switching on of first transistor 512 of pre-charge circuit 510 thereby connecting the bit line BL to the supply voltage ensuing pre-charging of the bit line BL, indicated as 544. As the voltage on the bit line BL rises to the pre-charge voltage VPCat time t1, the output of voltage detector circuit 520 drops to a logic low, indicated as 546. This results in the output of voltage detector circuit 520 (that is, the bit line feedback BLFB signal) to drop to a logic high. Dropping of the bit line feedback BLFB signal to a logic high results in an output of AND logic 514 dropping to a logic low which causes first transistor 512 of pre-charge circuit 510 to switch off. Switching off of first transistor 512 results in the bit line BL getting disconnected from the supply voltage VDD. Hence, the bit line BL is pre-charged to the pre-charge voltage VPC. In some examples, the pre-charge voltage VPC is greater than the threshold voltage of sensing circuit 120 but less than the supply voltage VDD, and can be changed by changing size of one or both of first transistor 524 and second transistor 526 of first example circuit diagram 522.

FIG. 14D is a second example circuit diagram 550 of voltage detector circuit 520. Second example circuit diagram 550 includes four additional transistors for voltage detector circuit 552 compared to first example circuit diagram 522. For example, and as shown in second example circuit diagram 550, voltage detector circuit 520 includes first transistor 524, second transistor 526, third transistor 552, a fourth transistor 554, a fifth transistor 556, and a sixth transistor 558. A first S/D structure of first transistor 524 is connected to the supply voltage VDD and a second S/D structure of first transistor 524 is connected to first internal node 560. A gate structure of first transistor 556 is connected to an input node that is connected to an input terminal. The input terminal is also the first terminal of voltage detector circuit 520 and is connected to the bit line BL.

A first S/D structure of second transistor 526 is connected to a second internal node 562 and a second S/D structure of second transistor 526 is connected to the ground. A gate structure of second transistor 526 is connected to the input node. A first S/D structure of third transistor 552 is connected to first internal node 560 and a second S/D structure of third transistor 552 is connected to an output node that is connected to an output terminal. The output terminal is also the second terminal of voltage detector circuit 520 and is connected to a second input terminal of NAND logic 514 of pre-charge circuit 510. A gate structure of third transistor 552 is connected to the input node.

A first S/D structure of fourth transistor 554 is connected to the output node and a second S/D structure of fourth transistor 554 is connected to second internal node 562. A gate structure of fourth transistor 554 is connected to the input node. A first S/D structure of fifth transistor 556 is connected to first internal node 560 and a second S/D structure of fifth transistor 556 is connected to the ground. A gate structure of fifth transistor 556 is connected to the output node. A first S/D structure of sixth transistor 558 is connected to second internal node 562 and a second S/D structure of sixth transistor 558 is connected to the supply voltage. A gate structure of sixth transistor 558 is connected to the output node. In examples, each of first transistor 524, third transistor 552, and fifth transistor 556 are PMOS transistors and each of second transistor 526, fourth transistor 554, and sixth transistor 558 are NMOS transistors. However, each of first transistor 524, third transistor 552, and fifth transistor 556 can be NMOS transistors and each of second transistor 526, fourth transistor 554, and sixth transistor 558 can be PMOS transistors. In some examples, voltage detector circuit 520 of FIG. 14D is also referred to as Schmitt trigger inverter.

FIG. 14E is a third example circuit diagram 580 of voltage detector circuit 520. Third example circuit diagram 580 includes two additional transistors for voltage detector circuit 520 compared to first example circuit diagram 522. As shown in third example circuit diagram 580, voltage detector circuit 520 includes first transistor 524, second transistor 526, a third transistor 582, and a fourth transistor 584. A first S/D structure of first transistor 524 is connected to the supply voltage VDD and a second S/D structure of first transistor 526 is connected to an output node that is connected to an output terminal. The output terminal is also the second terminal of voltage detector circuit 520 and is connected to a second input terminal of NAND logic 514 of pre-charge circuit 510. A gate structure of first transistor 524 is connected to an input node that is connected to an input terminal. The input terminal is also the first terminal of voltage detector circuit 520 and is connected to the bit line BL.

A first S/D structure of second transistor 526 is connected to a first internal node 586 and a second S/D structure of second transistor 526 is connected to the ground. A gate structure of second transistor 526 is connected to the input node. A first S/D structure of third transistor 582 is connected to the output node and a second S/D structure of third transistor 582 is connected to first internal node 586. A gate structure of third transistor 582 is connected to the input node. A first S/D structure of fourth transistor 584 is connected to first internal node 586 and a second S/D structure of fourth transistor 584 is connected to the supply voltage VDD. A gate structure of fourth transistor 584 is connected to the output node. In examples, each of third transistor 582 and fourth transistor 584 are NMOS transistors. However, each of third transistor 582 and fourth transistor 584 can be PMOS transistors.

FIG. 14F is an example graph 590 illustrating signals at the input and output terminals of voltage detector circuit 520 associated with each of second example circuit diagram 550 of FIG. 14D and third example circuit diagram 580 of FIG. 14E. As shown in FIG. 14E, when the input signal Vin is lower than the pre-charge voltage VPC (that is, the bit line BL voltage is below the pre-charge voltage VPC), the output signal Vout (that is, the bit line feedback BLFB signal) is at a logic high. When the input signal (that is, the bit line BL voltage) reaches the pre-charge voltage VPC, the output signal Vout (that is, the bit line feedback BLFB signal) drops to a logic low.

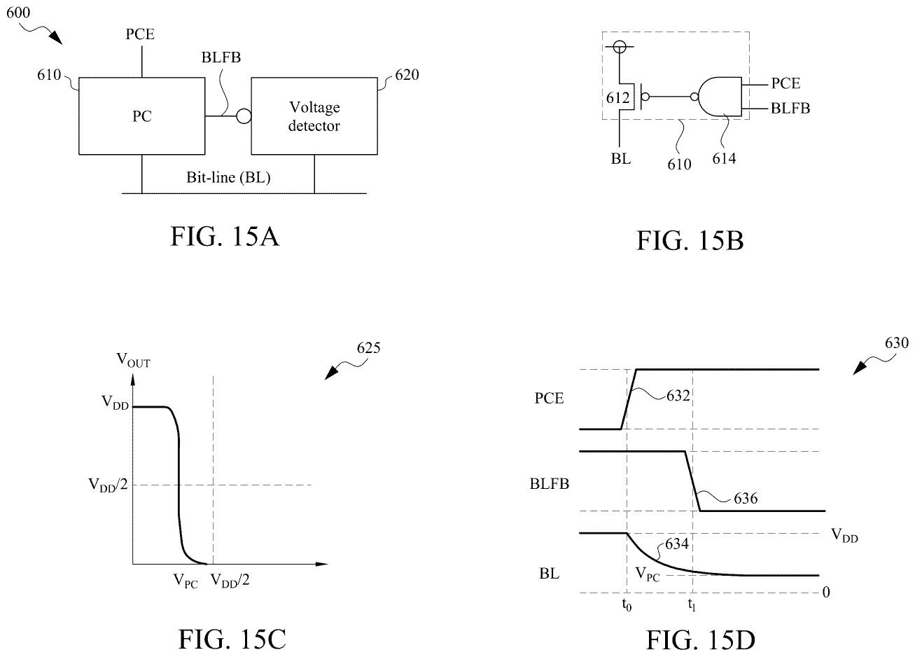

FIG. 15A is a block diagram of a voltage-controlled low pre-charge circuit 600. Voltage-controlled low pre-charge circuit 600 pre-charges a bit line BL to a threshold voltage for a read or a write operation that is lower than one half of the supply voltage but greater than 0V. As shown in FIG. 15A, voltage-controlled low pre-charge circuit 600 includes a low pre-charge circuit 610 and a low voltage detector circuit 620. Low pre-charge circuit 610 includes a first terminal configured to receive a pre-charge enable PCE signal, a second terminal to receive a bit line feedback BLFB signal, and a third terminal connected to a bit line BL. In examples, low pre-charge circuit 610 is enabled by the pre-charge enable PCE signal and pre-charges the bit line BL.

Low voltage detector circuit 620 includes a first terminal connected to the bit line BL and a second terminal connected to the second terminal of low pre-charge circuit 610. Low voltage detector circuit 620 is configured to sense the bit line voltage, and generate and provide the bit line feedback BLFB signal to low pre-charge circuit 610. Low pre-charge circuit 610 then can alter pre-charging of the bit line BL based on the bit line feedback BLFB signal. In examples, low voltage detector circuit 620 can be similar to voltage detector circuit 520 as discussed above with respect to FIGS. 14A, 14B, 14D, and 14F.

FIG. 15B is an example circuit diagram of low pre-charge circuit 610. As shown on FIG. 15B, low pre-charge circuit 610 includes a first transistor 612 and a NAND logic 614. A first S/D structure of first transistor 612 is connected to the ground voltage and a second S/D structure of first transistor 612 is connected to the bit line BL. A gate structure of first transistor 612 is connected to an output terminal of NAND logic 614. A first input terminal of NAND logic 614 is connected to receive the pre-charge enable PCE signal and a second input terminal of NAND logic 614 is connected to receive the bit line feedback BLFB signal. In some examples, first transistor 612 is a PMOS transistor.

FIG. 15C is a graph 625 illustrating signals at the input and output terminals of low voltage detector circuit 620. As shown in FIG, 15C, when the input signal Vin is lower than the pre-charge voltage VPC (that is, the bit line BL voltage is below the pre-charge voltage VPC), the output signal Vout (that is, the bit line feedback BLFB signal) is at a logic high. When the input signal (that is, the bit line BL voltage) reaches the pre-charge voltage VPC, the output signal Vout (that is, the bit line feedback BLFB signal) drops to a logic low. The pre-charge voltage VPC is lower than the threshold voltage of sensing circuit 120 and higher than 0V.

FIG. 15D is a timing diagram 630 of signals of voltage-controlled low pre-charge circuit 600. As shown in FIG. 15D, the pre-charging of the bit-line BL is triggered when the pre-charge enable PCE signal rises to a logic high at time t0, indicated as 632. Since, the voltage of the bit line BL is higher than the pre-charge voltage VPC when the pre-charging of the bit-line BL is triggered, the output of low voltage detector circuit 620 is a logic high. Hence, an output of NAND logic 614 of low pre-charge circuit 610 is a logic high. This results in switching on of first transistor 612 of low pre-charge circuit 610 thereby connecting the bit line BL to the ground ensuing pre-charging of the bit line BL, indicated as 534. As the voltage on the bit line BL discharges to the pre-charge voltage VPC at time t1, the output of low voltage detector circuit 620 rises to a logic high, indicated as 636. This results in the output of low voltage detector circuit 520 (that is, the bit line feedback BLFB signal) to drop to a logic low. Dropping of the bit line feedback BLFB signal to a logic low results in an output of NAND logic 614 rising to a logic high which causes first transistor 612 of low pre-charging circuit 610 to switch off. Switching off of first transistor 612 results in the bit line BL getting disconnected from the ground. Hence, the bit line BL is pre-charged to the pre-charge voltage VPC that is lower than the threshold voltage of sensing circuit 120 but greater than 0V, and can be changed by changing size of one or both of first transistor 524 and second transistor 526 of first example circuit diagram 522.

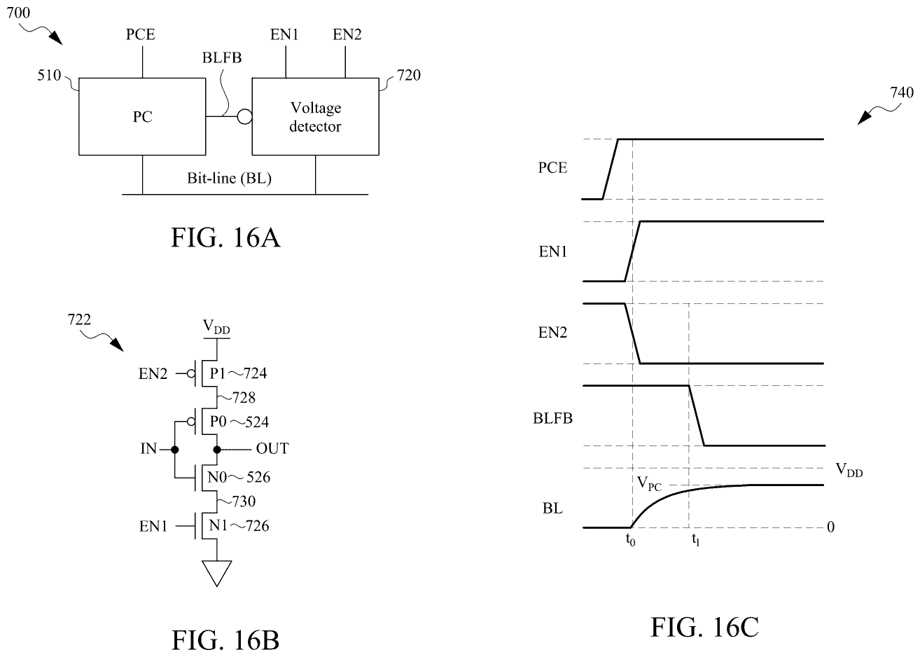

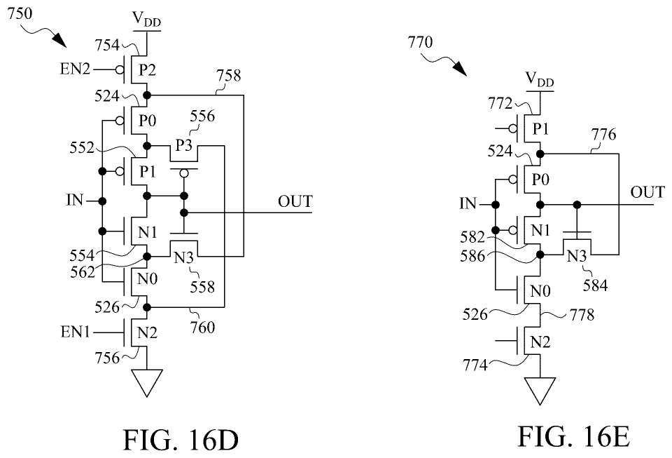

FIG. 16A is a block diagram of an enhanced voltage-controlled pre-charge circuit 700. Enhanced voltage-controlled pre-charge circuit 700 functions similar to voltage-controlled pre-charge circuit 500 of FIG. 12, and pre-charges a bit line BL to a pre-charge voltage VPC for a read operation that is greater than a threshold voltage of sensing circuit 102 but lower that the supply voltage VDD. As shown in FIG. 16A, enhanced voltage-controlled pre-charge circuit 700 includes pre-charge circuit 510 and an enhanced voltage detector circuit 720.

Enhanced voltage detector circuit 720 includes a first terminal connected to the bit line BL and a second terminal connected to the second terminal of pre-charge circuit 510. Enhanced voltage detector circuit 720 is configured to sense the bit line voltage, and to generate and provide the bit line feedback BLFB signal to pre-charge circuit 510. Pre-charge circuit 510 then can alter pre-charging of the bit line BL based on the bit line feedback BLFB signal. In examples, enhanced voltage detector circuit 720 is triggered by two enable signals instead of one used to trigger voltage detector circuit 520.

FIG. 16B is a first example circuit diagram 722 of enhanced voltage detector circuit 720. As shown in FIG. 16B, enhanced voltage detector circuit 720 includes two additional transistors compared to voltage detector circuit 520 of FIG. 14A. For example, enhanced voltage detector circuit 720 includes first transistor 524, second transistor 526, a third transistor 724, and a fourth transistor 728. A first S/D structure of third transistor 724 is connected to the supply voltage VDD and a second S/D structure of third transistor 724 is connected to a first internal node 728. The first S/D structure of first transistor 524 is connected to first internal node 728 and the second S/D structure of first transistor 524 is connected to an output node that is connected to an output terminal. The output terminal is same as the second terminal of voltage detector circuit 520. Hence, the output terminal is connected to pre-charge circuit 510 and provides the bit line feedback BLFB signal to pre-charge circuit 510. A first S/D structure of second transistor 526 is connected to the output node and a second S/D structure of second transistor 526 is connected to a second internal node 730. A first S/D structure of fourth transistor 726 is connected to second internal node 730 and a second S/D structure of fourth transistor 726 is connected to the ground.

The gate structure of first transistor 524 is connected to the gate structure of second transistor 526 at the input node that is connected to the input terminal. The input terminal is same as the first terminal of voltage detector circuit 520. Hence, the input terminal is connected to the bit line BL. A gate structure of third transistor 724 is connected to receive a first enable EN1 signal and a gate structure of fourth transistor 726 is connected to receive a second enable EN2 signal. Third transistor 724 is a PMOS transistor and fourth transistor 726 is a NMOS transistor. In some examples, different types of transistors may be used for both third transistor 724 and fourth transistor 726.

FIG. 16C is a timing diagram 740 of signals of enhanced voltage-controlled pre-charge circuit 700 of first example circuit diagram 722 of FIG. 16B. As shown in FIG. 16C, the pre-charging of the bit-line BL is triggered when the pre-charge enable PCE signal rises to a logic high. In addition, the first enable EN1 signal rises to a logic high and the second enable signal EN2 rises to a logic low at time t0. This results in switching on of third transistor 724 and fourth transistor 726. Since, the voltage of the bit line BL is below the pre-charge voltage VPC when the pre-charging of the bit-line BL is triggered, the output of enhanced voltage detector circuit 720 is a logic high. As the voltage on the bit line BL rises to the pre-charge voltage VPC at time t1, the output of enhanced voltage detector circuit 720 drops to a logic low. This results in the output of enhanced voltage detector circuit 720 (that is, the bit line feedback BLFB signal) to drop to a logic low. In some examples, the pre-charge voltage VPC is greater than the threshold voltage of sensing circuit 120 but less than the supply voltage VDD, and can be changed by changing size of one or both of first transistor 524 and second transistor 526 of first example circuit diagram 522.

FIG. 16D is a second example circuit diagram 750 of enhanced voltage detector circuit 720. Second example circuit diagram 750 includes two additional transistors for voltage detector circuit 720 compared to second example circuit diagram 550 of FIG. 14D. For example, and as shown in second example circuit diagram 750, voltage detector circuit 520 includes first transistor 524, second transistor 526, third transistor 552, fourth transistor 554, fifth transistor 556, sixth transistor 558, a seventh transistor 754, and an eighth transistor 754. A first S/D structure of seventh transistor 754 is connected to the supply voltage VDD and a second S/D structure of seventh transistor 754 is connected to a third internal node 758. A gate structure of seventh transistor 754 is connected to receive the second enable EN2 signal. A first S/D structure of first transistor 524 is connected to third internal node 758 and a second S/D structure of first transistor 524 is connected to first internal node 560. A gate structure of first transistor 556 is connected to an input node that is connected to an input terminal. The input terminal is also the first terminal of voltage detector circuit 520 and is connected to the bit line BL.

A first S/D structure of second transistor 526 is connected to a second internal node 562 and a second S/D structure of second transistor 526 is connected to a fourth internal node 760. A gate structure of second transistor 526 is connected to the input node. A first S/D structure of eighth transistor 756 is connected to fourth internal node 760 and a second S/D structure of eight transistor 756 is connected to the ground. A gate structure of eighth transistor 756 is connected to receive the first enable EN1 signal. A first S/D structure of third transistor 552 is connected to first internal node 560 and a second S/D structure of third transistor 552 is connected to an output node that is connected to an output terminal. The output terminal is also the second terminal of voltage detector circuit 520 and is connected to a second input terminal of NAND logic 514 of pre-charge circuit 510. A gate structure of third transistor 552 is connected to the input node.

A first S/D structure of fourth transistor 554 is connected to the output node and a second S/D structure of fourth transistor 554 is connected to second internal node 562. A gate structure of fourth transistor 554 is connected to the input node. A first S/D structure of fifth transistor 556 is connected to first internal node 560 and a second S/D structure of fifth transistor 556 is connected to the ground. A gate structure of fifth transistor 556 is connected to the output node. A first S/D structure of sixth transistor 558 is connected to second internal node 562 and a second S/D structure of sixth transistor 558 is connected to the supply voltage. A gate structure of sixth transistor 558 is connected to the output node. In examples, seventh transistor 754 is a PMOS transistor and eight transistor 756 is a NMOS transistor. However, seventh transistor 754 can be a NMOS transistor and eight transistor 756 can be a PMOS transistor. Enhanced voltage detector circuit 720 of second example circuit diagram 750 functions substantially similar to enhanced voltage detector circuit 720 of first example circuit diagram 722, and hence is not being described again for brevity of description.

FIG. 16E is a third example circuit diagram 770 of voltage detector circuit 720. Third example circuit diagram 770 includes two additional transistors for voltage detector circuit 720 compared to third example circuit diagram 580 of FIG. 14E. As shown in third example circuit diagram 770, voltage detector circuit 720 includes first transistor 524, second transistor 526, third transistor 582, fourth transistor 584, fifth transistor 722, sixth transistor 774. A first S/D structure of fifth transistor 772 is connected to the supply voltage VDD and a second S/D structure of fifth transistor 772 is connected to a second internal node 776. A gate of fifth transistor 772 is connected to receive the second enable EN2 signal. A first S/D structure of first transistor 524 is connected to second internal node 776 and a second S/D structure of first transistor 526 is connected to the output node that is connected to the output terminal. A gate structure of first transistor 524 is connected to an input node that is connected to an input terminal.

A first S/D structure of second transistor 526 is connected to a first internal node 586 and a second S/D structure of second transistor 526 is connected to third internal node 778. A gate structure of second transistor 526 is connected to the input node. A first S/D structure of eight transistor 774 is connected to third internal node 778 and a second S/D structure of eight transistor 774 is connected to the ground. A gate structure of eight transistor 774 is connected to receive the first enable EN1 signal. A first S/D structure of third transistor 582 is connected to the output node and a second S/D structure of third transistor 582 is connected to first internal node 586. A gate structure of third transistor 582 is connected to the input node. A first S/D structure of fourth transistor 584 is connected to first internal node 586 and a second S/D structure of fourth transistor 584 is connected to the supply voltage VDD. A gate structure of fourth transistor 584 is connected to the output node. In examples, each of third transistor 582 and fourth transistor 584 are NMOS transistors. However, each of third transistor 582 and fourth transistor 584 can be PMOS transistors. Enhanced voltage detector circuit 720 of third example circuit diagram 770 functions substantially similar to enhanced voltage detector circuit 720 of first example circuit diagram 722, and hence is not being described again for brevity of description.

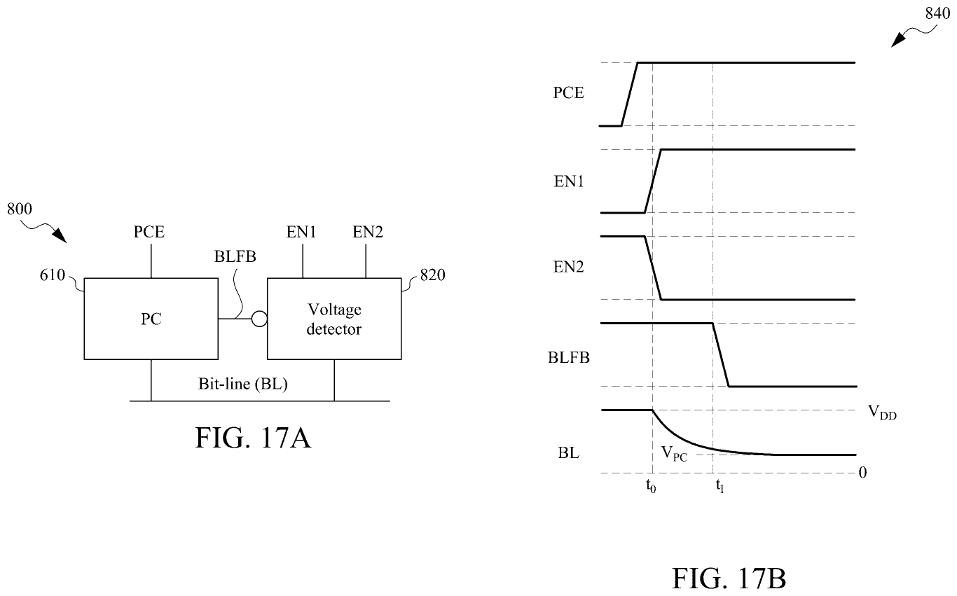

FIG. 17A is a block diagram of an enhanced voltage-controlled low pre-charge circuit 800. Enhanced voltage-controlled low pre-charge circuit 800 functions similar to voltage-controlled low pre-charge circuit 600 of FIG. 15A, and pre-charges a bit line BL to a pre-charge voltage VPC for a read or a write operation that is lower than a threshold voltage of sensing circuit 120 but higher that the ground voltage or 0V. As shown in FIG. 17A, enhanced voltage-controlled low pre-charge circuit 800 includes pre-charge circuit 610 and an enhanced low voltage detector circuit 820.

Enhanced low voltage detector circuit 820 includes a first terminal connected to the bit line BL and a second terminal connected to the second terminal of pre-charge circuit 810. Enhanced low voltage detector circuit 820 is configured to sense the bit line voltage, and generate and provide the bit line feedback BLFB signal to pre-charge circuit 810. Pre-charge circuit 810 then can alter pre-charging of the bit line BL based on the bit line feedback BLFB signal. In examples, enhanced voltage detector circuit 820 is triggered by two enable signals instead of one used to trigger voltage detector circuit 520. Enhanced low voltage detector circuit 820 functions substantially similar to enhanced voltage detector circuit 720 and hence is not being described again for brevity of description.

FIG. 17B is a timing diagram 840 of signals of enhanced voltage-controlled low pre-charge circuit 800. As shown in FIG. 17B, the pre-charging of the bit-line BL is triggered when the pre-charge enable PCE signal rises to a logic high. In addition, the first enable EN1 signal rises to a logic high and the second enable signal EN2 rises to a logic low at time t0. This results in the discharging to the bit line BL from a logic high. As the voltage on the bit line BL drops to the pre-charge voltage VPC, the bit line feedback BLFB signal rises to a logic high thereby halting any further discharge of the bit line BL.

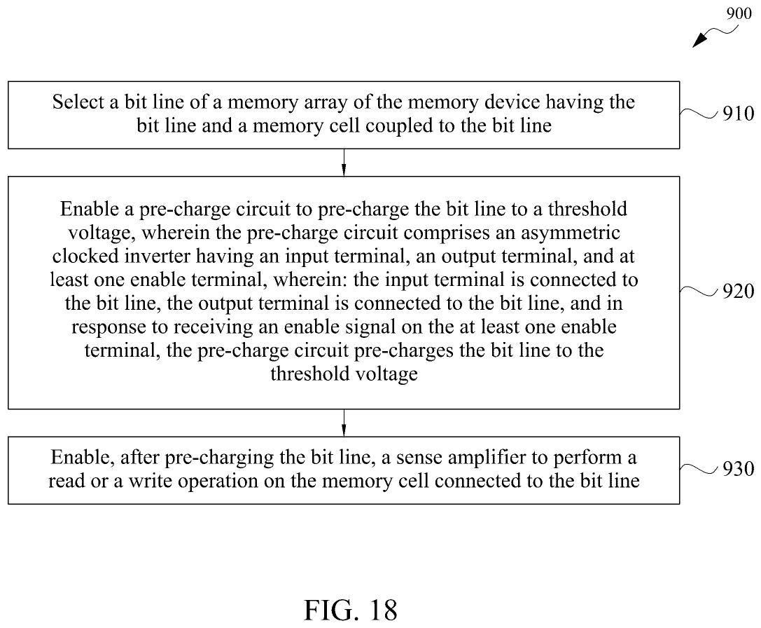

FIG. 18 is a flow diagram of a method 900 for pre-charging a bile BL of a memory device. At stage 910 of method 900, a bit line BL of a memory array of the memory device is selected. The memory array may include the bit line and a memory cell coupled to the bit line.

At stage 920 of method 900, a pre-charge circuit is enabled to to pre-charge the bit line to a pre-charge voltage. The pre-charge circuit may include an asymmetric clocked inverter having an input terminal, an output terminal, and at least one enable terminal. The input terminal is connected to the bit line. The output terminal is connected to the bit line. In response to receiving an enable signal on the at least one enable terminal, the pre-charge circuit pre-charges the bit line to a threshold voltage.

At stage 930 of method 900, sensing circuit 120 is enabled to perform the read operation on the memory cell connected to the bit line. As discussed above, the pore-charge voltage can be higher than a threshold voltage of sensing circuit 120 and lower than the supply voltage VDD. In another example, the pre-charge voltage can be lower than a threshold voltage of sensing circuit 120 and higher than the ground voltage.

In accordance with example embodiments, a semiconductor device comprises: a memory array having a bit line and a memory cell coupled to the bit line; a sensing circuit configured to sense data from the memory cell; and a pre-charge circuit comprising an asymmetric clocked inverter having an input terminal, an output terminal, and at least one enable terminal, wherein: the input terminal is connected to the bit line, the output terminal is connected to the bit line, and in response to receiving an enable signal on the at least one enable terminal, the pre-charge circuit pre-charges the bit line to a pre-charge voltage, wherein the pre-charge voltage is higher than a threshold voltage of a sensing circuit and lower than the supply voltage.

In accordance with other example embodiments, a semiconductor device comprises: a memory array having a bit line and a memory cell coupled to the bit line; a pre-charge circuit comprising a first terminal, a second terminal, and at least one enable terminal, wherein the first terminal is connected to the bit line, and wherein in response to receiving an enable signal on the at least one enable terminal, the pre-charge circuit pre-charges the bit line to a pre-charge voltage; and a voltage detector circuit comprising a first terminal and a second terminal, wherein the first terminal of the voltage detector is connected to the bit line, wherein the second terminal of the voltage detector is connected to the second terminal of the pre-charge circuit, wherein the voltage detector is configured to sense a bit line voltage of the bit line and provide a bit line feedback signal to the pre-charge circuit based on the sensed bit line voltage, and wherein the pre-charge circuit is configured to alter pre-charging of the bit line based on the bit line feedback signal.

In accordance with another example embodiments, a method of performing a read operation on a memory device, comprises: selecting a bit line of a memory array of the memory device, having a bit line and a memory cell coupled to the bit line; enabling a pre-charge circuit to pre-charge the bit line to a pre-charge voltage, wherein the pre-charge circuit comprises an asymmetric clocked inverter having an input terminal, an output terminal, and at least one enable terminal, wherein: the input terminal is connected to the bit line, the output terminal is connected to the bit line, and in response to receiving an enable signal on the at least one enable terminal, the pre-charge circuit pre-charges the bit line to the pre-charge voltage; and enabling, after charging the bit line, a sensing circuit to perform the read operation on a memory cell connected to the bit line.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a memory array having a bit line and a memory cell coupled to the bit line;
a sensing circuit configured to sense data from the memory cell; and
a pre-charge circuit comprising an asymmetric clocked inverter having an input terminal, an output terminal, and at least one enable terminal, wherein:
the input terminal is connected to the bit line,
the output terminal is connected to the bit line, and
in response to receiving an enable signal on the at least one enable terminal, the pre-charge circuit pre-charges the bit line to a pre-charge voltage, wherein the pre-charge voltage is higher than a threshold voltage of the sensing circuit and lower than the supply voltage.

2. The semiconductor device of claim 1, wherein the memory array is a Read Only Memory (ROM) array.

3. The semiconductor device of claim 1, wherein the pre-charge circuit comprises a first transistor, a second transistor, a third transistor, and a fourth transistor, wherein the first transistor and the second transistor together are connected to form a diode, and wherein the transistor is connected between the supply voltage and a first terminal of the diode, and wherein the fourth transistor is connected between a second terminal of the diode and the ground.

4. The semiconductor device of claim 3, wherein a first Source/Drain (S/D) structure of the third transistor is connected to the supply voltage VDD and a second S/D structure of the third transistor is connected to a first S/D structure of the first transistor at a first internal node, wherein a second S/D structure of the first transistor is connected to a first S/D structure of the second transistor at an output node, wherein the output node is connected to the output terminal, wherein a second S/D structure of the second transistor is connected to a first S/D structure of the fourth transistor at a second internal node, wherein a second S/D structure of the fourth transistor is connected to the ground, wherein a gate structure of the first transistor is connected to a gate structure of the second transistor at an input node that is connected to the input terminal, wherein a gate structure of the fourth transistor is connected to a first enable terminal to receive a first enable signal and a gate structure of the third transistor is connected to a second enable terminal to receive a second enable signal.

5. The semiconductor device of claim 3, further comprising a fifth transistor connected in parallel to the first transistor.

6. The semiconductor device of claim 5, wherein a third enable signal is provided to a gate of the fifth transistor.

7. The semiconductor device of claim 3, wherein the threshold voltage is tuned based on a size or a voltage threshold of one or more of the third transistor and the fourth transistor.

8. The semiconductor device of claim 1, further comprising:
a voltage detector circuit connected to the bit line, wherein the voltage detector circuit is configured to provide a feedback signal to the pre-charge circuit based on a bit line voltage.

9. The semiconductor device of claim 1, wherein the pre-charge voltage is greater than 0.6 times of the supply voltage.

10. A semiconductor device comprising:
a memory array having a bit line and a memory cell coupled to the bit line;
a pre-charge circuit comprising a first terminal, a second terminal, and at least one enable terminal, wherein the first terminal is connected to the bit line, and wherein in response to receiving apre-charge enable signal on the at least one enable terminal, the pre-charge circuit pre-charges the bit line to a pre-charge voltage; and
a voltage detector circuit comprising a first terminal and a second terminal, wherein the first terminal of the voltage detector is connected to the bit line, wherein the second terminal of the voltage detector is connected to the second terminal of the pre-charge circuit, wherein the voltage detector is configured to sense a bit line voltage of the bit line and provide a bit line feedback signal to the pre-charge circuit based on the sensed bit line voltage, and wherein the pre-charge circuit is configured to alter pre-charging of the bit line based on the bit line feedback signal.

11. The semiconductor device of claim 10, wherein the pre-char circuit comprises a first transistor and a AND logic, wherein a first Source/Drain (S/D) structure of first transistor is connected to a supply voltage and a second S/D structure of the first transistor is connected to the bit line, wherein a gate structure of the first transistor is connected to an output terminal of the AND logic, wherein a first input terminal of the AND logic is connected to receive the pre-charge enable signal and a second input terminal of the AND logic is connected to receive an inverted bit line feedback signal.

12. The semiconductor device of claim 10, wherein the voltage detector circuit comprises a second transistor and a third transistor, wherein a first S/D structure of the second transistor is connected to the supply voltage and a second S/D structure of the second transistor is connected to an output node that is connected to the second terminal, a first S/D structure of the third transistor is connected to the output node and a second S/D structure of the third transistor is connected to the ground, and wherein a gate structure of the second transistor is connected to a gate structure of the third transistor at an input node that is connected to the first terminal.

13. The semiconductor device of claim 12, wherein the pre-charge voltage is tuned based on a size or a voltage threshold of one or more of the second transistor and the third transistor.

14. The semiconductor device of claim 10, wherein the pre-charge voltage is greater than a threshold voltage of a sensing circuit and lower than the supply voltage.

15. The semiconductor device of claim 10, wherein the pre-charge voltage is greater than 0.6 times of the supply voltage.

16. The semiconductor device of claim 10, wherein the pre-charge voltage is lower than a threshold voltage of a sensing circuit and higher than a ground voltage.

17. The semiconductor device of claim 10, wherein the pre-charge voltage is lower than 0.4 times of the supply voltage.

18. A method of performing a read operation on a memory device, the method comprising:
selecting a bit line of a memory array of the memory device, and the memory device having a memory cell coupled to the bit line;
enabling a pre-charge circuit to pre-charge the bit line to a pre-charge voltage, wherein the pre-charge circuit comprises an asymmetric clocked inverter having an input terminal, an output terminal, and at least one enable terminal, wherein:
the input terminal is connected to the bit line,
the output terminal is connected to the bit line, and
in response to receiving an enable signal on the at least one enable terminal, the pre-charge circuit pre-charges the bit line to the pre-charge voltage; and
enabling, after pre-charging of the bit line, a sensing circuit to perform a read operation on the memory cell connected to the bit line.

19. The method of claim 18, wherein enabling the pre-charge circuit to pre-charge the bit line to the pre-charge voltage comprises enabling the pre-charge circuit to pre-charge the bit line to the pre-charge voltage that is higher than a threshold voltage of the sensing circuit and lower than the supply voltage.

20. The method of claim 18, wherein enabling the pre-charge circuit to pre-charge the bit line to the pre-charge voltage comprises enabling the pre-charge circuit to pre-charge the bit line to the threshold voltage that is lower than a threshold voltage of the sensing circuit and higher than a ground voltage.
